(19) United States
(12) Patent Application Publication
(10) Pub. No.: US 2025/0174473 A1
(43) Pub. Date: May 29, 2025

(54) DICING DEVICE, SEMICONDUCTOR CHIP MANUFACTURING METHOD, AND SEMICONDUCTOR CHIP

(71) Applicant: YAMAHA HATSUDOKI KABUSHIKI KAISHA, Iwata-shi, Shizuoka-ken (JP)

(72) Inventor: Yoshikuni SUZUKI, Iwata-shi, Shizuoka (JP)

(73) Assignee: YAMAHA HATSUDOKI KABUSHIKI KAISHA, Iwata-shi, Shizuoka-ken (JP)

(21) Appl. No.: 18/841,856

(22) PCT Filed: Apr. 27, 2022
(86) PCT No.: PCT/JP2022/019196

§ 371 Date: Aug. 27, 2024

(51) Int. Cl. H01L 21/67; B23K 26/04; B23K 26/08; B23K 26/40; B23K 26/53; B23K 101/40; H01L 21/68; H01L 21/687; H01L 21/78; H01L 23/544

(52) U.S. Cl. CPC H01L 21/67092; B23K 26/048; B23K 26/0853; B23K 26/40; B23K 26/53; H01L 21/67259; H01L 21/681; H01L 21/68764; H01L 21/78; H01L 23/544; B23K 2101/40; H01L 2223/54426

(57) ABSTRACT

A dicing device includes a table unit to move a wafer and rotate the wafer, a laser irradiator to emit a laser beam to the wafer, an imager to image a plurality of alignment marks of a plurality of semiconductor chips on the wafer, and a height meter to measure a height position of a surface of the wafer.

### CROSS-REFERENCE TO RELATED APPLICATION

This application is a National Stage of International Patent Application No. PCT/JP2022/019196, filed Apr. 27, 2022, the entire content of which is incorporated herein by reference.

### BACKGROUND

### Technical Field

The present disclosure relates to a dicing device, a semiconductor chip manufacturing method, and a semiconductor chip, and more particularly, it relates to a dicing device including a laser irradiator to emit a laser beam, a semiconductor chip manufacturing method, and a semiconductor chip.

### Background Art

Conventionally, a dicing device including a laser irradiator to emit a laser beam is known. Such a dicing device is disclosed in Japanese Patent Laid-Open No. 2019-016731, for example.

Japanese Patent Laid-Open No. 2019-016731 discloses a laser processing apparatus including a laser beam irradiation unit to emit a laser beam. The laser processing apparatus includes a chuck table and an imaging unit.

The chuck table holds a wafer. The imaging unit images the wafer held by the chuck table. In the laser processing apparatus, after the wafer is held by the chuck table, the coordinates of an edge of the wafer are acquired based on an image of the edge of the wafer captured by the imaging unit. In the laser processing apparatus, the center position of the wafer acquired based on three or more sets of coordinates of the edge of the wafer is aligned with the center position of the chuck table set in advance. Thus, the position of the wafer in a horizontal direction is adjusted.

### SUMMARY

In the laser processing apparatus disclosed in Japanese Patent Laid-Open No. 2019-016731, the imaging unit is used to adjust only the position of the wafer in the horizontal direction, and thus it is not possible to adjust the focus of the laser beam emitted from the laser beam irradiation unit on the wafer.

Accordingly, the present disclosure provides a dicing device capable of adjusting the position of a wafer in a horizontal direction and adjusting the focus of a laser beam emitted from a laser irradiator on the wafer.

A dicing device according to a first aspect of the present disclosure includes a table unit to move a wafer including a plurality of semiconductor chips in at least one of a first direction in a horizontal direction or a second direction in the horizontal direction perpendicular to the first direction and rotate the wafer, while holding the wafer, a laser irradiator to emit a laser beam to the wafer moved or rotated while being held by the table unit in order to dice the wafer into the plurality of semiconductor chips, an imager to image a plurality of alignment marks of the plurality of semiconductor chips on the wafer, and a height meter to measure a height position of a surface of the wafer. The term “dicing” indicates a broader concept including not only cutting a wafer with a laser beam into a plurality of semiconductor chips, but also forming a modified layer in the wafer by the laser beam and then dividing the wafer along the modified layer.

As described above, the dicing device according to the first aspect of the present disclosure includes the imager to image the plurality of alignment marks of the plurality of semiconductor chips on the wafer, and the height meter to measure the height position of the surface of the wafer. Accordingly, based on the alignment marks imaged by the imager, the wafer is moved and/or rotated by the table unit such that the position of the wafer in the horizontal direction can be adjusted. Furthermore, the height position of the surface of the wafer can be acquired based on the height position measured by the height meter, and thus the focus of the laser beam emitted from the laser irradiator on the wafer can be adjusted based on the height position of the surface of the wafer. Consequently, the position of the wafer in the horizontal direction can be adjusted, and the focus of the laser beam emitted from the laser irradiator on the wafer can be adjusted.

The dicing device according to the first aspect preferably further includes a controller configured or programmed to control the imager to image the plurality of alignment marks while simultaneously controlling the height meter to measure height positions of the wafer. Accordingly, the height positions of the surface of the wafer can be acquired at positions at which the alignment marks are imaged by the imager, and thus as compared with a case in which the alignment marks are imaged by the imager at positions different from positions at which the height positions of the surface of the wafer are acquired, an increase in the number of times that the wafer is moved in the first direction and the second direction in the horizontal direction by the table unit can be reduced or prevented.

In such a case, the imager preferably includes an imager lifting mechanism to move the imager in an upward-downward direction to adjust an imaging focus of the imager, and the controller is preferably configured or programmed to perform a control to acquire positions of two alignment marks imaged with the imaging focus of the imager adjusted among the plurality of alignment marks by moving the imager in the upward-downward direction using the imager lifting mechanism to adjust the imaging focus in order to adjust a position of the wafer in the horizontal direction. Accordingly, the two actual alignment marks on the wafer can be clearly imaged by the imager, and thus the two alignment marks can be accurately identified from other configurations. Consequently, the position of the wafer in the horizontal direction can be adjusted based on the two accurate alignment marks, and thus the position of the wafer in the horizontal direction can be accurately adjusted.

In the dicing device including the controller configured or programmed to control the imager to image the alignment marks while simultaneously controlling the height meter to measure height positions of the wafer, the imager and the height meter are preferably linearly aligned in a predetermined direction in which a first alignment mark and a second alignment mark among the plurality of alignment marks are aligned. Accordingly, at a position at which the first alignment mark is imaged by the imager, the height meter can measure the height position shifted in the predetermined direction. Furthermore, at a position at which the second alignment mark is imaged by the imager, the height meter can measure the height position shifted in the predetermined direction. Thus, the inclination of a straight portion passing through the two height positions on the wafer with respect to the horizontal direction can be acquired. When the two height positions are measured, the first alignment mark and the second alignment mark are imaged in parallel such that information can be acquired to determine whether or not the first alignment mark and the second alignment mark have been imaged by the imager when the wafer is excessively inclined and it is difficult to adjust the imaging focus of the imager.

In the dicing device including the imager and the height meter linearly aligned in the predetermined direction, the controller is preferably configured or programmed to perform a control to acquire, based on a difference between a first height position of a portion of the wafer shifted in the predetermined direction from a first arrangement position at which the first alignment mark is arranged and a second height position of a portion of the wafer shifted in the predetermined direction from a second arrangement position at which the second alignment mark is arranged, whether or not the first alignment mark and the second alignment mark have been imaged when a straight portion passing through the first height position and the second height position of the wafer is inclined outside an allowable range with respect to the horizontal direction. Accordingly, it is possible to identify whether or not the first alignment mark and the second alignment mark have been imaged by the imager when the straight portion passing through the two height positions on the wafer is excessively inclined, based on the difference between the first height position and the second height position. Consequently, it is possible to identify whether or not the first alignment mark and the second alignment mark have been imaged by the imager when the wafer is excessively inclined such that it is difficult to adjust the imaging focus of the imager.

In the dicing device including the controller configured or programmed to acquire whether or not the first alignment mark and the second alignment mark have been imaged when the straight portion passing through the first height position and the second height position of the wafer is inclined outside the allowable range with respect to the horizontal direction, the controller is preferably configured or programmed to perform a control to image the first alignment mark after adjusting, using the imager lifting mechanism, the imaging focus of the imager at a position at which the first alignment mark at the first arrangement position is imaged based on the first height position of the wafer, and to image the second alignment mark after adjusting, using the imager lifting mechanism, the imaging focus of the imager at a position at which the second alignment mark at the second arrangement position is imaged based on the second height position of the wafer. Accordingly, the imaging focus of the imager arranged at the position at which the first alignment mark at the first arrangement position is imaged is adjusted based on the first height position of the portion of the wafer shifted in the predetermined direction from the first arrangement position at which the first alignment mark is arranged, and thus it is difficult to image the first alignment mark with the imaging focus adjusted unless the surface of the wafer is nearly horizontal. Furthermore, the imaging focus Fc1 of the imager arranged at the position at which the second alignment mark at the second arrangement position is imaged is adjusted based on the second height position of the portion of the wafer shifted in the predetermined direction from the second arrangement position at which the second alignment mark is arranged, and thus it is difficult to image the second alignment mark with the imaging focus adjusted unless the surface of the wafer is nearly horizontal. Thus, when the difference between the first height position and the second height position is within the allowable range and the surface of the wafer is nearly horizontal, the first alignment mark and the second alignment mark are imaged with the imaging focus adjusted, and thus the position of the wafer in the horizontal direction can be adjusted based on the first alignment mark and the second alignment mark. Consequently, it is possible to prevent an imaging process for imaging alignment marks other than the first alignment mark and the second alignment mark to be performed, and thus an increase in the processing time in the dicing device can be reduced or prevented.

In the dicing device including the controller configured or programmed to perform a control to image the first alignment mark after adjusting the imaging focus based on the first height position, and to image the second alignment mark after adjusting the imaging focus based on the second height position, the controller is preferably configured or programmed to perform a control to specify a height plane of the wafer based on the first height position, the second height position, and a third height position measured by the height meter at an arrangement position of a third alignment mark that is not on a straight line extending in the predetermined direction. Accordingly, the imaging focus of the imager for imaging the plurality of alignment marks on the wafer can be accurately adjusted based on the height plane of the wafer, and thus the imager can clearly image the alignment marks. Furthermore, the laser focus of the laser beam emitted from the laser irradiator can be adjusted to a position according to the height plane of the wafer using the height plane of the wafer, and thus an appropriate position on the wafer can be processed by the laser beam.

In the dicing device including the controller configured or programmed to acquire the height plane of the wafer, the controller is preferably configured or programmed to, when the difference between the first height position and the second height position is outside an allowable range, perform a control to enable positional adjustment of the wafer in the horizontal direction based on the third alignment mark imaged by the imager with the imaging focus adjusted based on a specified height plane, and the first alignment mark or the second alignment mark imaged by the imager with the imaging focus adjusted based on the specified height plane. Accordingly, the third alignment mark and the first alignment mark or the second alignment mark can be imaged by the imager with the imaging focus accurately adjusted based on the height plane of the wafer, and thus the third alignment mark and the first alignment mark or the second alignment mark can be clearly imaged. Consequently, the position of the third alignment mark and the position of the first alignment mark or the position of the second alignment mark can be reliably acquired, and thus the table unit moves and/or rotates the wafer such that the positional adjustment of the wafer in the horizontal direction is enabled.

In the dicing device including the controller configured or programmed to acquire the height plane of the wafer, the controller is preferably configured or programmed to control the height meter to measure the third height position without imaging the third alignment mark at the arrangement position of the third alignment mark using the imager when the difference between the first height position and the second height position is within an allowable range. Accordingly, even when the third alignment mark is not imaged, the position of the wafer in the horizontal direction can be adjusted based on the first alignment mark and the second alignment mark, and thus the processing time in the dicing device can be reduced by the amount of time required to image the third alignment mark.

The dicing device including the controller configured or programmed to acquire the height plane of the wafer preferably further includes a laser lifting mechanism to move the laser irradiator in the upward-downward direction to adjust a laser focus of the laser beam, and the controller is preferably configured or programmed to perform a control to emit, to the wafer, the laser beam with the laser focus adjusted while simultaneously adjusting, using the laser lifting mechanism, a height position of the laser irradiator based on the height plane of the wafer specified based on height positions of three points on the wafer measured by the height meter. Accordingly, the height position of the laser irradiator is adjusted by the laser lifting mechanism based on the height plane of the wafer such that the laser focus of the laser beam emitted from the laser irradiator can be adjusted to an appropriate position according to the height plane of the wafer, and thus as compared with a case in which the table unit including the mechanism to move and rotate the wafer in the first direction and the second direction in the horizontal direction is moved in the upward-downward direction, an increase in the driving force of a drive source required for the lifting mechanism can be reduced or prevented. Consequently, a relatively small drive source can be used for the lifting mechanism, and thus an increase in the size of the dicing device can be reduced or prevented.

In the dicing device according to the first aspect, the imager preferably includes an infrared camera. Accordingly, it is possible to image infrared light reflected by the alignment marks provided on the wafer and transmitted through the wafer, and thus even when the alignment marks are provided on the side of the wafer closer to the sheet member, it is possible to image the alignment marks provided on the wafer. Furthermore, even when the alignment marks are provided on the side of the wafer opposite to the sheet member, it is possible to image the infrared light reflected by the alignment marks, and thus the alignment marks provided on the wafer can be imaged. Consequently, the alignment marks can be imaged both when the alignment marks are provided on the side of the wafer closer to the sheet member and when the alignment marks are provided on the side of the wafer opposite to the sheet member.

In the dicing device including the imager and the height meter linearly aligned in the predetermined direction, the imager preferably includes a first camera and a second camera, the first camera preferably has a wider angle of view than the second camera, and the second camera preferably has a higher resolution than the first camera. Accordingly, when a plurality of wafers of the same type are processed in the dicing device, the accuracy of positioning the wafer in the horizontal direction has not been confirmed when the first wafer is processed. Thus, the first camera capable of imaging the wafer at a wider angle of view is used when the first alignment mark and the second alignment mark are imaged such that the first alignment mark and the second alignment mark can be more reliably imaged. Furthermore, when a plurality of wafers of the same type are processed in the dicing device, the first alignment mark and the second alignment mark are imaged a plurality of times by the first camera until the exact positions of the first alignment mark and the second alignment mark can be acquired, and then the first alignment mark and the second alignment mark can be imaged by the second camera. Consequently, after it becomes possible to reliably image the first alignment mark and the second alignment mark, the first alignment mark and the second alignment mark can be clearly imaged.

A semiconductor chip manufacturing method according to a second aspect of the present disclosure includes imaging, by an imager, a plurality of alignment marks of a plurality of semiconductor chips on a wafer, measuring, by a height meter, a height position of a surface of the wafer, and emitting a laser beam to the wafer from a laser irradiator operable to emit the laser beam in order to dice the wafer into the plurality of semiconductor chips. The term “dicing” indicates a broader concept including not only cutting a wafer with a laser beam into a plurality of semiconductor chips, but also forming a modified layer in the wafer by the laser beam and then dividing the wafer along the modified layer.

As described above, the semiconductor chip manufacturing method according to the second aspect of the present disclosure includes imaging, by the imager, the plurality of alignment marks of the plurality of semiconductor chips on the wafer, and measuring, by the height meter, the height position of the surface of the wafer. Accordingly, the position of the wafer in the horizontal direction can be adjusted based on the alignment marks imaged by the imager. Furthermore, the height position of the surface of the wafer can be acquired based on the height position measured by the height meter, and thus the laser focus of the laser beam emitted from the laser irradiator on the wafer can be adjusted based on the height position of the surface of the wafer. Consequently, it is possible to obtain the semiconductor chip manufacturing method that enables the position of the wafer in the horizontal direction to be adjusted and the focus of the laser beam emitted from the laser irradiator on the wafer to be adjusted.

A semiconductor chip according to the third aspect of the present disclosure is manufactured by a dicing device including a table unit to move a wafer including a plurality of semiconductor chips in at least one of a first direction in a horizontal direction or a second direction in the horizontal direction perpendicular to the first direction and rotate the wafer, while holding the wafer, a laser irradiator to emit a laser beam to the wafer moved or rotated while being held by the table unit in order to dice the wafer into the plurality of semiconductor chips, an imager to image a plurality of alignment marks of the plurality of semiconductor chips on the wafer, and a height meter to measure a height position of a surface of the wafer.

As described above, the semiconductor chip according to the third aspect of the present disclosure is manufactured by the dicing device including the imager to image the plurality of alignment marks of the plurality of semiconductor chips on the wafer, and the height meter to measure the height position of the surface of the wafer. Accordingly, based on the alignment marks imaged by the imager, the wafer is moved and/or rotated by the table unit such that the position of the wafer in the horizontal direction can be adjusted. Furthermore, the height position of the surface of the wafer can be acquired based on the height position measured by the height meter, and thus the laser focus of the laser beam emitted from the laser irradiator on the wafer can be adjusted based on the height position of the surface of the wafer. Consequently, it is possible to obtain the semiconductor chip manufactured by the dicing device capable of adjusting the position of the wafer in the horizontal direction and adjusting the laser focus of the laser beam emitted from the laser irradiator on the wafer.

According to the present disclosure, as described above, it is possible to adjust the position of the wafer in the horizontal direction and adjust the focus of the laser beam emitted from the laser irradiator on the wafer.

### BRIEF DESCRIPTION OF THE DRAWINGS

FIG. 1 is a plan view showing a semiconductor wafer processing apparatus including a dicing device and an expanding device according to a first embodiment;

FIG. 2 is a plan view showing a wafer ring structure to be processed in the semiconductor wafer processing apparatus according to the first embodiment;

FIG. 3 is a sectional view taken along the line III-III in FIG. 2;

FIG. 4 is a plan view of the dicing device arranged adjacent to the expanding device according to the first embodiment;

FIG. 5 is a side view showing the dicing device arranged adjacent to the expanding device according to the first embodiment, as viewed from the Y2 direction side;

FIG. 6 is a plan view of the expanding device according to the first embodiment;

FIG. 7 is a side view showing the expanding device according to the first embodiment, as viewed from the Y2 direction side;

FIG. 8 is a side view showing the expanding device according to the first embodiment, as viewed from the X1 direction side;

FIG. 9 is a block diagram showing the control configuration of the semiconductor wafer processing apparatus according to the first embodiment;

FIG. 10 is a flowchart of the first half of a semiconductor chip manufacturing process of the semiconductor wafer processing apparatus according to the first embodiment;

FIG. 11 is a flowchart of the second half of the semiconductor chip manufacturing process of the semiconductor wafer processing apparatus according to the first embodiment;

FIG. 12 is a side view showing the laser focus of a laser irradiator, the imaging focus of a high-resolution camera, and the imaging focus of a wide-angle camera in the dicing device according to the first embodiment;

FIG. 13 is a sectional view showing modified layers of a wafer after dicing by the laser irradiator in the dicing device according to the first embodiment;

FIG. 14 is a plan view showing alignment marks provided on a plurality of semiconductor chips on the wafer in the dicing device according to the first embodiment;

FIG. 15 is a side view showing a height adjuster in the dicing device according to the first embodiment;

FIG. 16 is a plan view showing the high-resolution camera, a height meter, and the wide-angle camera in the dicing device according to the first embodiment;

FIG. 17 is a schematic view showing a state before a first alignment mark, a second alignment mark, and a third alignment mark are imaged by the high-resolution camera in the dicing device according to the first embodiment;

FIG. 18 is a schematic view showing a state in which the first alignment mark on the wafer has been moved to align with the position of the high-resolution camera by a chuck table unit in the dicing device according to the first embodiment;

FIG. 19 is a sectional view taken along the line XIX-XIX in FIG. 18, showing a state in which the first height position of a portion of the wafer shifted in a predetermined direction from the first alignment mark is measured by the height meter in the dicing device according to the first embodiment;

FIG. 20 is a sectional view taken along the line XIX-XIX in FIG. 18, showing a state in which the first alignment mark is imaged by an imager, the imaging focus of which has been adjusted based on the first height position, in the dicing device according to the first embodiment;

FIG. 21 is a schematic view showing a state in which the second alignment mark on the wafer has been moved to align with the position of the high-resolution camera by the chuck table unit in the dicing device according to the first embodiment;

FIG. 22 is a sectional view taken along the line XXII-XXII in FIG. 21, showing a state in which the second height position of a portion of the wafer shifted in the predetermined direction from the second alignment mark is measured by the height meter in the dicing device according to the first embodiment;

FIG. 23 is a sectional view taken along the line XXII-XXII in FIG. 21, showing a state in which the second alignment mark is imaged by the imager, the imaging focus of which has been adjusted based on the second height position, in the dicing device according to the first embodiment;

FIG. 24 is a schematic view showing a state in which the third alignment mark on the wafer has been moved to align with the position of the high-resolution camera by the chuck table unit in the dicing device according to the first embodiment;

FIG. 25 is a schematic view showing the height plane of the wafer acquired in the dicing device according to the first embodiment;

FIG. 26 is a schematic view showing a state in which the first alignment mark on the wafer has been moved again to align with the position of the high-resolution camera by the chuck table unit in the dicing device according to the first embodiment;

FIG. 27 is a sectional view corresponding to the sectional view taken along the line XXII-XXII in FIG. 21, showing a state in which a difference between the first height position and the second height position is within an allowable range in the dicing device according to the first embodiment;

FIG. 28 is a flowchart of the first half of an alignment information acquisition process of the semiconductor wafer processing apparatus according to the first embodiment;

FIG. 29 is a flowchart of the second half of the alignment information acquisition process of the semiconductor wafer processing apparatus according to the first embodiment;

FIG. 30 is a plan view showing a semiconductor wafer processing apparatus including a dicing device and an expanding device according to a second embodiment;

FIG. 31 is a side view showing the semiconductor wafer processing apparatus including the dicing device and the expanding device according to the second embodiment, as viewed from the Y2 direction side;

FIG. 32 is a side view showing the semiconductor wafer processing apparatus including the dicing device and the expanding device according to the second embodiment, as viewed from the X1 direction side;

FIG. 33 is a block diagram showing the control configuration of the semiconductor wafer processing apparatus according to the second embodiment;

FIG. 34 is a flowchart of the first half of a semiconductor chip manufacturing process of the semiconductor wafer processing apparatus according to the second embodiment; and

FIG. 35 is a flowchart of the second half of the semiconductor chip manufacturing process of the semiconductor wafer processing apparatus according to the second embodiment.

### DETAILED DESCRIPTION

Embodiments embodying the present disclosure are hereinafter described on the basis of the drawings.

### First Embodiment

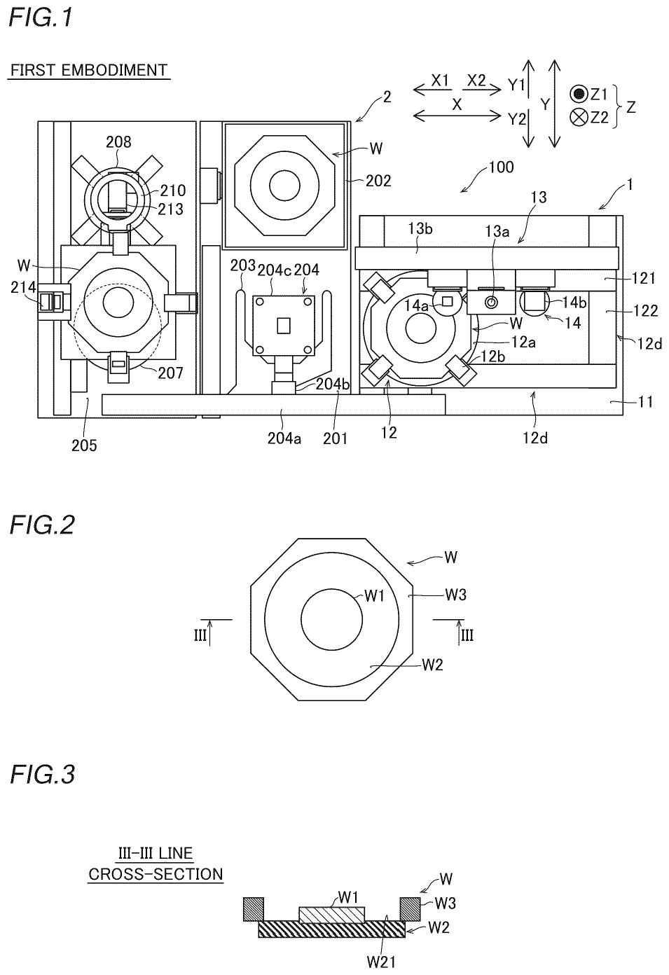

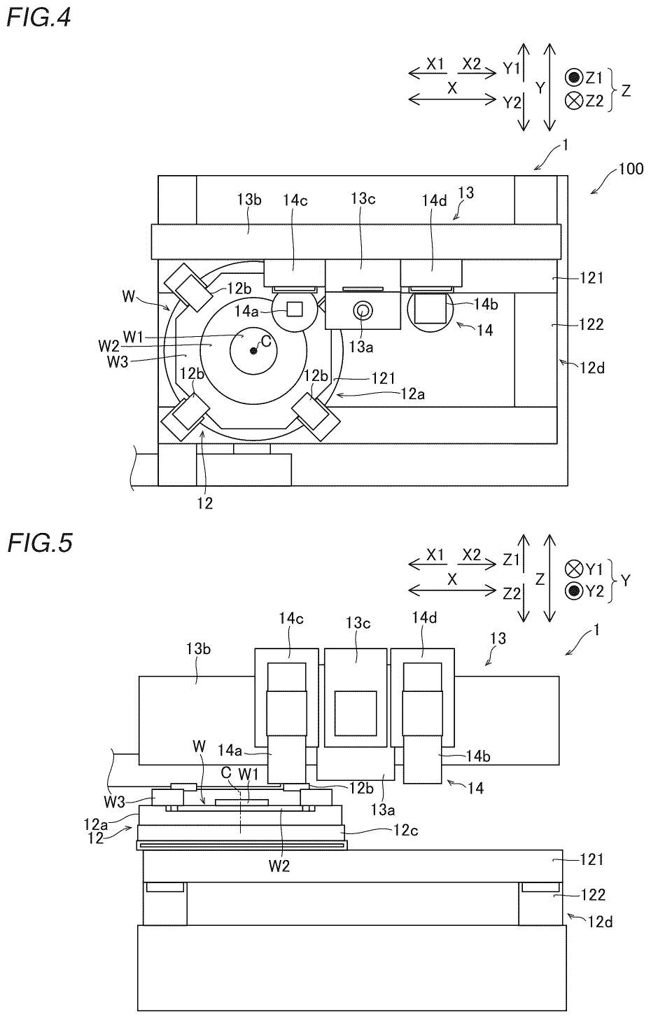

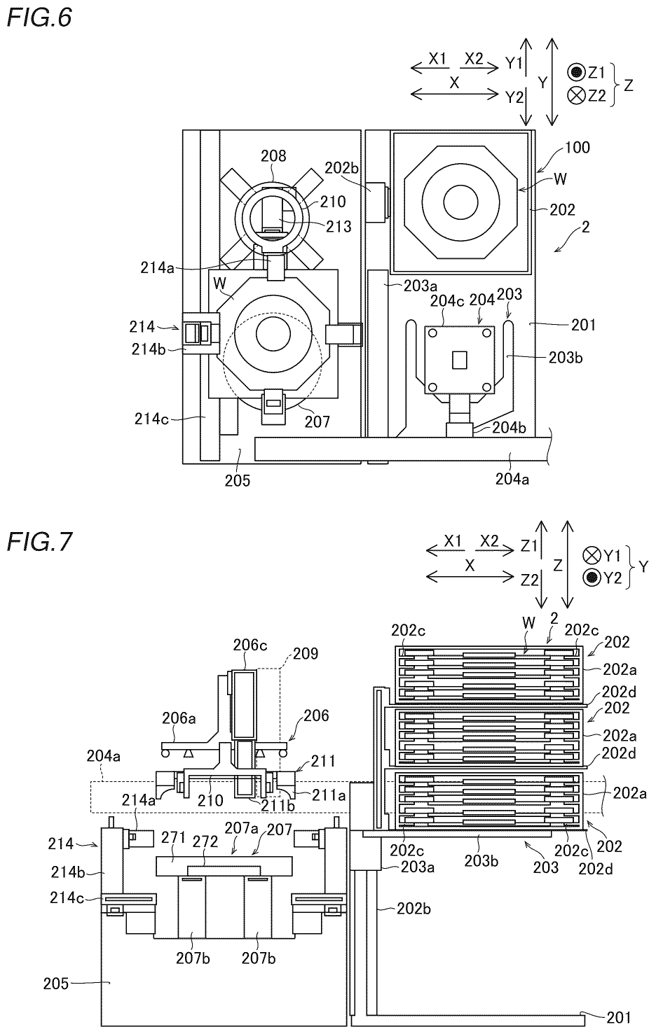

The configuration of a semiconductor wafer processing apparatus 100 according to a first embodiment of the present disclosure is now described with reference to FIGS. 1 to 29.

### Semiconductor Wafer Processing Apparatus

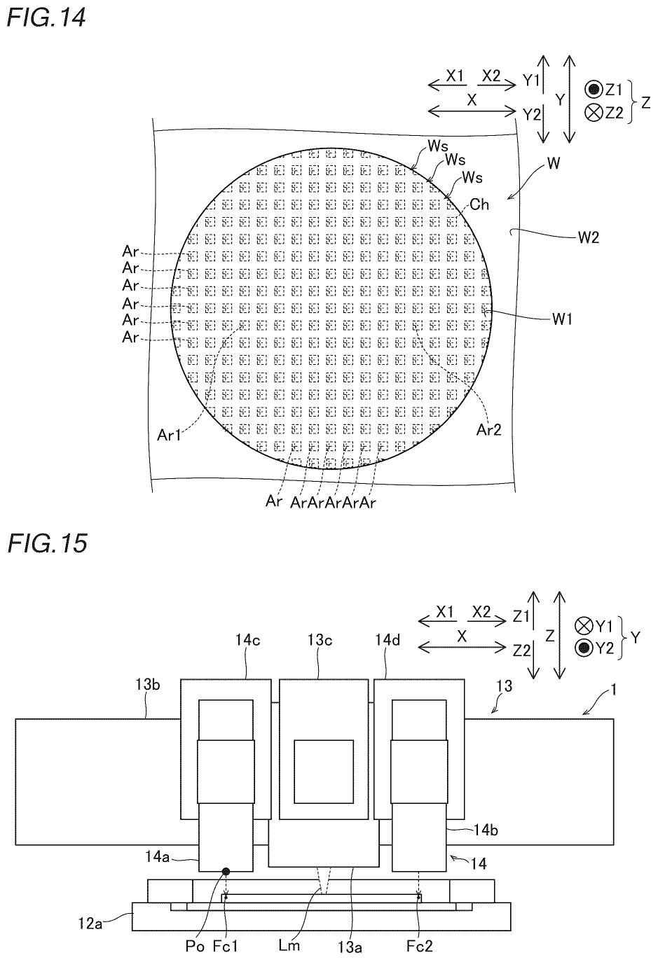

As shown in FIG. 1, the semiconductor wafer processing apparatus 100 is an apparatus that processes a wafer W1 provided on a wafer ring structure W. The semiconductor wafer processing apparatus 100 forms a modified layer Wm (see FIG. 13) in the wafer W1 and divides the wafer W1 along the modified layer Wm to form a plurality of semiconductor chips Ch (see FIG. 14).

The wafer ring structure W is now described with reference to FIGS. 2 and 3. The wafer ring structure W includes the wafer W1, a sheet member W2, and a ring-shaped member W3.

The wafer W1 is a circular thin plate made of a crystal of a semiconductor material that is used as a material for a semiconductor integrated circuit. Inside the wafer W1, the modified layer Wm is formed by modifying the inside along a dividing line by processing in the semiconductor wafer processing apparatus 100. That is, the wafer W1 is processed so as to be divisible along the dividing line. The sheet member W2 is an elastic adhesive tape. An adhesive layer is provided on the upper surface W21 of the sheet member W2. The wafer W1 is attached to the adhesive layer on the sheet member W2. The ring-shaped member W3 is a ring-shaped metal frame in a plan view. The ring-shaped member W3 is attached to the adhesive layer on the sheet member W2 while surrounding the wafer W1.

The semiconductor wafer processing apparatus 100 includes a dicing device 1 and an expanding device 2. Hereinafter, an upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 2 are aligned is defined as an X direction, a direction from the dicing device 1 toward the expanding device 2 in the X direction is defined as an X1 direction, and a direction from the expanding device 2 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

As shown in FIGS. 1, 4, and 5, the dicing device 1 emits a laser having a wavelength transmissive to the wafer W1 along the dividing line (street Ws) to form the modified layer Wm. The modified layer Wm refers to a crack, a void, or the like formed inside the wafer W1 by the laser. A method for forming the modified layer Wm in the wafer W1 in this manner is called dicing.

Specifically, the dicing device 1 includes a base 11, a chuck table unit 12, a laser 13, and an imager 14. The chuck table unit 12 is an example of a “table unit” in the claims.

The base 11 is a base on which the chuck table unit 12 is installed. The base 11 has a rectangular shape in the plan view.

### Chuck Table Unit

The chuck table unit 12 includes a suction unit 12a, clamps 12b, a rotation mechanism 12c, and a table movement mechanism 12d. The suction unit 12a suctions the wafer ring structure W on the upper surface of the suction unit 12a on the Z1 direction side. The suction unit 12a is a table including a suction hole, a suction pipe line, etc. to suction the lower surface of the ring-shaped member W3 of the wafer ring structure W on the Z2 direction side. The suction unit 12a is supported by the table movement mechanism 12d via the rotation mechanism 12c. The clamps 12b are provided at an upper end of the suction unit 12a. The clamps 12b hold the wafer ring structure W suctioned by the suction unit 12a. The clamps 12b hold the ring-shaped member W3 of the wafer ring structure W suctioned by the suction unit 12a from the Z1 direction side. In this manner, the wafer ring structure W is held by the suction unit 12a and the clamps 12b.

The rotation mechanism 12c rotates the suction unit 12a in a circumferential direction around a rotation center axis C extending parallel to the Z direction. The rotation mechanism 12c is attached to an upper end of the table movement mechanism 12d. The table movement mechanism 12d moves the wafer ring structure W in the X and Y directions. The table movement mechanism 12d includes an X-direction movement mechanism 121 and a Y-direction movement mechanism 122. The X-direction movement mechanism 121 moves the rotation mechanism 12c in the X1 direction or the X2 direction. The X-direction movement mechanism 121 includes a linear conveyor module, or a ball screw and a drive including a motor with an encoder, for example. The Y-direction movement mechanism 122 moves the rotation mechanism 12c in the Y1 direction or the Y2 direction. The Y-direction movement mechanism 122 includes a linear conveyor module, or a ball screw and a drive including a motor with an encoder, for example.

### Laser

The laser 13 emits a laser beam La to the wafer W1 of the wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c. The laser irradiator 13a emits a pulsed laser beam. The mounting member 13b is a frame to which the laser 13 and the imager 14 are mounted. The Z-direction movement mechanism 13c moves the laser 13 in the Z1 direction or the Z2 direction. The Z-direction movement mechanism 13c includes a linear conveyor module, or a ball screw and a drive including a motor with an encoder, for example. The laser irradiator 13a may be a laser irradiator that oscillates a continuous wave laser beam other than a pulsed laser beam as the laser beam La as long as a modified layer Wm can be formed by multiphoton absorption. The Z-direction movement mechanism 13c is an example of a “laser lifting mechanism” in the claims.

### Imager

The imager 14 images the wafer W1 of the wafer ring structure W held by the chuck table unit 12. The imager 14 is arranged on the Z1 direction side of the chuck table unit 12. The imager 14 includes a high-resolution camera 14a, a wide-angle camera 14b, a Z-direction movement mechanism 14c, and a Z-direction movement mechanism 14d. The high-resolution camera 14a is an example of a “first camera” in the claims. The wide-angle camera 14b is an example of a “second camera” in the claims. The Z-direction movement mechanism 14c and the Z-direction movement mechanism 14d are examples of an “imager lifting mechanism” in the claims.

The high-resolution camera 14a and the wide-angle camera 14b are near-infrared imaging cameras. The high-resolution camera 14a has a narrower viewing angle than the wide-angle camera 14b. The high-resolution camera 14a has a higher resolution than the wide-angle camera 14b. The wide-angle camera 14b has a wider viewing angle than the high-resolution camera 14a. The wide-angle camera 14b has a lower resolution than the high-resolution camera 14a. The high-resolution camera 14a is arranged on the X1 direction side of the laser irradiator 13a. The wide-angle camera 14b is arranged on the X2 direction side of the laser irradiator 13a. Thus, the high-resolution camera 14a, the laser irradiator 13a, and the wide-angle camera 14b are arranged adjacent to each other in this order from the X1 direction side toward the X2 direction side.

The Z-direction movement mechanism 14c moves the high-resolution camera 14a in the Z1 direction or the Z2 direction. The Z-direction movement mechanism 14c includes a linear conveyor module, or a ball screw and a drive including a motor with an encoder, for example. The Z-direction movement mechanism 14d moves the wide-angle camera 14b in the Z1 direction or the Z2 direction. The Z-direction movement mechanism 14d includes a linear conveyor module, or a ball screw and a drive including a motor with an encoder, for example.

### Expanding Device

As shown in FIGS. 1, 6, and 7, the expanding device 2 divides the wafer W1 to form the plurality of semiconductor chips Ch (see FIG. 14). The expanding device 2 forms a sufficient gap between the plurality of semiconductor chips Ch. A modified layer Wm is formed in the wafer W1 by emitting a laser having a wavelength transmissive to the wafer W1 along the dividing line (street Ws) in the dicing device 1. In the expanding device 2, the plurality of semiconductor chips Ch are formed by dividing the wafer W1 along the modified layer Wm formed in advance in the dicing device 1.

Therefore, in the expanding device 2, the wafer W1 is divided along the modified layer Wm by expanding the sheet member W2. Furthermore, in the expanding device 2, the gap between the plurality of semiconductor chips Ch formed by division is widened by expanding the sheet member W2.

The expanding device 2 includes a base 201, a cassette unit 202, a lift-up hand unit 203, a suction hand unit 204, a base 205, a cool air supplier 206, a cooling unit 207, an expander 208, a base 209, an expansion maintaining member 210, a heat shrinker 211, an ultraviolet irradiator 212, a squeegee unit 213, and a clamp unit 214.

### Base

The base 201 is a base on which the cassette unit 202 and the lift-up hand unit 203 are installed. The base 201 has a rectangular shape in the plan view.

### Cassette Unit

The cassette unit 202 can accommodate a plurality of wafer ring structures W. The cassette unit 202 includes wafer cassettes 202a, a Z-direction movement mechanism 202b, and pairs of placement portions 202c.

A plurality of (three) wafer cassettes 202a are arranged in the Z direction. Each of the wafer cassettes 202a has an accommodation space capable of accommodating a plurality of (five) wafer ring structures W. The wafer ring structure W is manually supplied and placed in the wafer cassette 202a. The wafer cassette 202a may accommodate one to four wafer ring structures W, or may accommodate six or more wafer ring structures W. Furthermore, one, two, or four or more wafer cassettes 202a may be arranged in the Z direction.

The Z-direction movement mechanism 202b moves the wafer cassettes 202a in the Z1 direction or the Z2 direction. The Z-direction movement mechanism 202b includes a linear conveyor module, or a ball screw and a drive including a motor with an encoder, for example. The Z-direction movement mechanism 202b also includes mounting tables 202d that support the wafer cassettes 202a from below. A plurality of (three) mounting tables 202d are arranged according to the positions of the plurality of wafer cassettes 202a.

A plurality of (five) pairs of placement portions 202c are arranged inside the wafer cassette 202a. The ring-shaped member W3 of the wafer ring structure W is placed on the pair of placement portions 202c from the Z1 direction side. One of the pair of placement portions 202c protrudes in the X2 direction from the inner surface of the wafer cassette 202a on the X1 direction side. The other of the pair of placement portions 202c protrudes in the X1 direction from the inner surface of the wafer cassette 202a on the X2 direction side.

### Lift-Up Hand Unit

The lift-up hand unit 203 can take out the wafer ring structure W from the cassette unit 202. Furthermore, the lift-up hand unit 203 can take the wafer ring structure W into the cassette unit 202.

Specifically, the lift-up hand unit 203 includes a Y-direction movement mechanism 203a and a lift-up hand 203b. The Y-direction movement mechanism 203a includes a linear conveyor module, or a ball screw and a drive including a motor with an encoder, for example. The lift-up hand 203b supports the ring-shaped member W3 of the wafer ring structure W from the Z2 direction side.

### Suction Hand Unit

The suction hand unit 204 suctions the ring-shaped member W3 of the wafer ring structure W from the Z1 direction side.

Specifically, the suction hand unit 204 includes an X-direction movement mechanism 204a, a Z-direction movement mechanism 204b, and a suction hand 204c. The X-direction movement mechanism 204a moves the suction hand 204c in the X direction. The Z-direction movement mechanism 204b moves the suction hand 204c in the Z direction. Each of the X-direction movement mechanism 204a and the Z-direction movement mechanism 204b includes a linear conveyor module, or a ball screw and a drive including a motor with an encoder, for example. The suction hand 204c suctions and supports the ring-shaped member W3 of the wafer ring structure W from the Z1 direction side. The suction hand 204c supports the ring-shaped member W3 of the wafer ring structure W by generating a negative pressure.

### Base

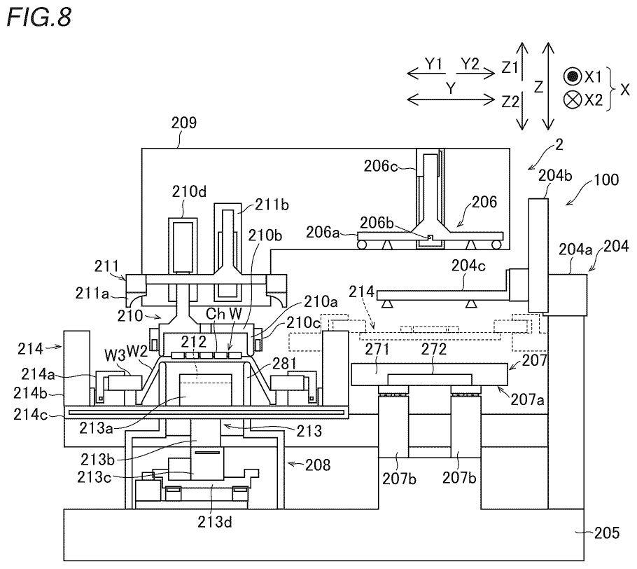

As shown in FIGS. 7 and 8, the base 205 is a base on which the expander 208, the cooling unit 207, the ultraviolet irradiator 212, and the squeegee unit 213 are installed. The base 205 has a rectangular shape in the plan view. In FIG. 8, the clamp unit 214 arranged on the Z1 direction side of the cooling unit 207 is indicated by dotted lines.

### Cool Air Supplier

The cool air supplier 206 supplies cool air to the sheet member W2 from the Z1 direction side when the sheet member W2 is expanded by the expander 208.

Specifically, the cool air supplier 206 includes a supplier main body 206a, a cool air supply port 206b, and a movement mechanism 206c. The cool air supply port 206b allows cool air supplied from a cool air supply device to flow out therethrough. The cool air supply port 206b is provided at an end of the supplier main body 206a on the Z2 direction side. The cool air supply port 206b is arranged in a central portion of the end of the supplier main body 206a on the Z2 direction side. The movement mechanism 206c includes a linear conveyor module, or a ball screw and a motor with an encoder, for example.

The cool air supply device is a device that generates cool air. The cool air supply device supplies air cooled by a heat pump, for example. Such a cool air supply device is installed on the base 205. The cool air supplier 206 and the cool air supply device are connected to each other by a hose (not shown).

### Cooling Unit

The cooling unit 207 cools the sheet member W2 from the Z2 direction side.

Specifically, the cooling unit 207 includes a cooling member 207a including a cooling body 271 and a Peltier element 272, and a Z-direction movement mechanism 207b. The cooling body 271 is made of a member having a large heat capacity and a high thermal conductivity. The cooling body 271 is made of metal such as aluminum. The Peltier element 272 cools the cooling body 271. The cooling body 271 is not limited to aluminum, and may be another member having a large heat capacity and a high thermal conductivity. The Z-direction movement mechanism 207b is a cylinder.

The cooling unit 207 is movable in the Z1 direction or the Z2 direction by the Z-direction movement mechanism 207b. Thus, the cooling unit 207 is movable to a position contacting the sheet member W2 and a position spaced apart from the sheet member W2.

### Expander

The expander 208 expands the sheet member W2 of the wafer ring structure W to divide the wafer W1 along the dividing line.

Specifically, the expander 208 includes an expanding ring 281. The expanding ring 281 expands the sheet member W2 by supporting the sheet member W2 from the Z2 direction side. The expanding ring 281 has a ring shape in the plan view. The structure of the expanding ring 281 is described in detail below.

### Base

The base 209 is a base material on which the cool air supplier 206, the expansion maintaining member 210, and the heat shrinker 211 are installed.

### Expansion Maintaining Member

As shown in FIGS. 7 and 8, the expansion maintaining member 210 holds down the sheet member W2 from the Z1 direction side such that the sheet member W2 in the vicinity of the wafer W1 does not shrink due to heating by a heating ring 211a.

Specifically, the expansion maintaining member 210 includes a pressing ring 210a, a lid 210b, and an intake 210c. The pressing ring 210a has a ring shape in the plan view. The lid 210b is provided on the pressing ring 210a to cover an opening of the pressing ring 210a. The intake 210c is an intake ring having a ring shape in the plan view. A plurality of intake ports are formed in the lower surface of the intake 210c on the Z2 direction side. The pressing ring 210a is moved in the Z direction by a Z-direction movement mechanism 210d. That is, the Z-direction movement mechanism 210d moves the pressing ring 210a to a position at which the sheet member W2 is held down and a position away from the sheet member W2. The Z-direction movement mechanism 210d includes a linear conveyor module, or a ball screw and a drive including a motor with an encoder, for example.

### Heat Shrinker

The heat shrinker 211 shrinks the sheet member W2 expanded by the expander 208 by heating while maintaining the gap between the plurality of semiconductor chips Ch.

The heat shrinker 211 includes the heating ring 211a and a Z-direction movement mechanism 211b. The heating ring 211a has a ring shape in the plan view. The heating ring 211a includes a sheathed heater that heats the sheet member W2. The Z-direction movement mechanism 211b moves the heating ring 211a in the Z direction. The Z-direction movement mechanism 211b includes a linear conveyor module, or a ball screw and a drive including a motor with an encoder, for example.

### Ultraviolet Irradiator

The ultraviolet irradiator 212 emits ultraviolet rays Ut to the sheet member W2 in order to reduce the adhesive strength of the adhesive layer of the sheet member W2. Specifically, the ultraviolet irradiator 212 includes an ultraviolet illuminator. The ultraviolet irradiator 212 is arranged at an end of a press 213a of the squeegee unit 213, which is described below, on the Z1 direction side. The ultraviolet irradiator 212 emits the ultraviolet rays Ut to the sheet member W2 while moving together with the squeegee unit 213.

### Squeegee Unit

The squeegee unit 213 further divides the wafer W1 along the modified layer Wm by locally pressing the wafer W1 from the Z2 direction side after the sheet member W2 is expanded. Specifically, the squeegee unit 213 includes the press 213a, a Z-direction movement mechanism 213b, an X-direction movement mechanism 213c, and a rotation mechanism 213d.

The press 213a generates a bending stress in the wafer W1 to divide the wafer W1 along the modified layer Wm by being moved by the rotation mechanism 213d and the X-direction movement mechanism 213c while pressing the wafer W1 from the Z2 direction side via the sheet member W2. The press 213a presses the wafer W1 via the sheet member W2 by being raised to a raised position on the Z1 direction side by the Z-direction movement mechanism 213b. When the press 213a is lowered to a lowered position on the Z2 direction side by the Z-direction movement mechanism 213b, the wafer W1 is no longer pressed. The press 213a is a squeegee.

The press 213a is attached to an end of the Z-direction movement mechanism 213b on the Z1 direction side. The Z-direction movement mechanism 213b linearly moves the press 213a in the Z1 direction or the Z2 direction. The Z-direction movement mechanism 213b is a cylinder, for example. The Z-direction movement mechanism 213b is attached to an end of the X-direction movement mechanism 213c on the Z1 direction side.

The X-direction movement mechanism 213c is attached to an end of the rotation mechanism 213d on the Z1 direction side. The X-direction movement mechanism 213c linearly moves the press 213a in one direction. The X-direction movement mechanism 213c includes a linear conveyor module, or a ball screw and a drive including a motor with an encoder, for example.

In the squeegee unit 213, the press 213a is raised to the raised position by the Z-direction movement mechanism 213b. In the squeegee unit 213, the press 213a is moved in the Y direction by the X-direction movement mechanism 213c while locally pressing the wafer W1 from the Z2 direction side via the sheet member W2 such that the wafer W1 is divided. In the squeegee unit 213, the press 213a is lowered to the lowered position by the Z-direction movement mechanism 213b. In the squeegee unit 213, after the press 213a finishes moving in the Y direction, the press 213a is rotated 90 degrees by the rotation mechanism 213d.

In the squeegee unit 213, the press 213a is raised to the raised position by the Z-direction movement mechanism 213b. In the squeegee unit 213, after the press 213a is rotated 90 degrees, the press 213a is moved in the X direction by the X-direction movement mechanism 213c while locally pressing the wafer W1 from the Z2 direction side via the sheet member W2 such that the wafer W1 is divided.

### Clamp Unit

The clamp unit 214 holds the ring-shaped member W3 of the wafer ring structure W. Specifically, the clamp unit 214 includes a gripper 214a, a Z-direction movement mechanism 214b, and a Y-direction movement mechanism 214c. The gripper 214a supports the ring-shaped member W3 from the Z2 direction side and holds down the ring-shaped member W3 from the Z1 direction side. Thus, the ring-shaped member W3 is held by the gripper 214a. The gripper 214a is attached to the Z-direction movement mechanism 214b.

The Z-direction movement mechanism 214b moves the clamp unit 214 in the Z direction. Specifically, the Z-direction movement mechanism 214b moves the gripper 214a in the Z1 direction or the Z2 direction. The Z-direction movement mechanism 214b includes a linear conveyor module, or a ball screw and a drive including a motor with an encoder, for example. The Z-direction movement mechanism 214b is attached to the Y-direction movement mechanism 214c. The Y-direction movement mechanism 214c moves the Z-direction movement mechanism 214b in the Y1 direction or the Y2 direction. The Y-direction movement mechanism 214c includes a linear conveyor module, or a ball screw and a drive including a motor with an encoder, for example.

### Control Configuration of Semiconductor Wafer Processing Apparatus

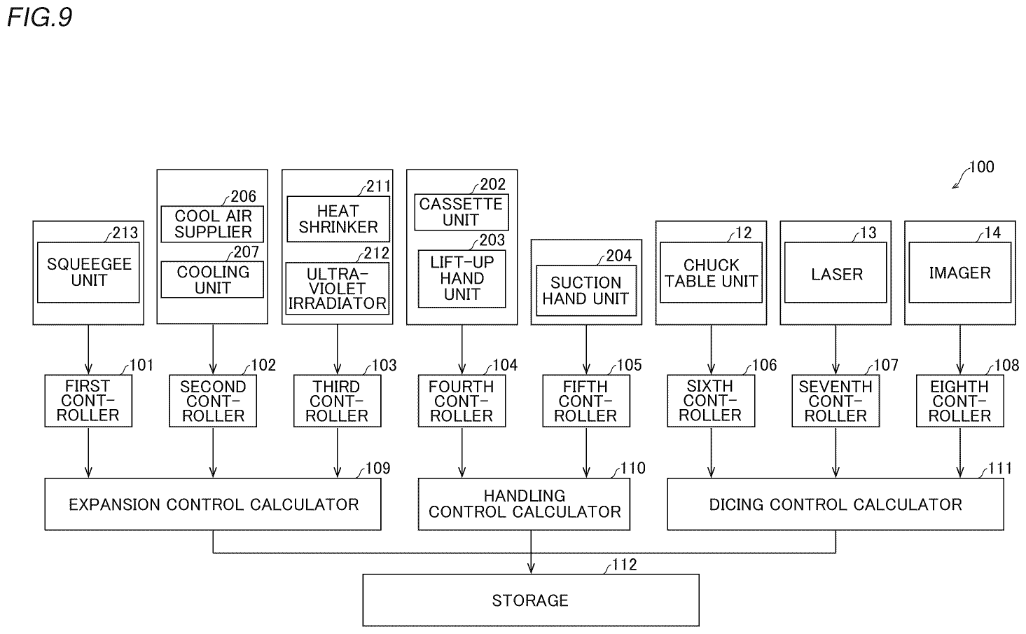

As shown in FIG. 9, the semiconductor wafer processing apparatus 100 includes a first controller 101, a second controller 102, a third controller 103, a fourth controller 104, a fifth controller 105, a sixth controller 106, a seventh controller 107, an eighth controller 108, an expansion control calculator 109, a handling control calculator 110, a dicing control calculator 111, and a storage 112. The dicing control calculator 111 is an example of a “controller” in the claims.

The first controller 101 controls the squeegee unit 213. The first controller 101 includes a central processing unit (CPU) and a storage including a read-only memory (ROM) and a random access memory (RAM), for example. The first controller 101 may include, as a storage, a hard disk drive (HDD) that retains stored information even after the voltage is cut off, for example. The HDD may be provided in common for the first controller 101, the second controller 102, the third controller 103, the fourth controller 104, the fifth controller 105, the sixth controller 106, the seventh controller 107, and the eighth controller 108.

The second controller 102 controls the cool air supplier 206 and the cooling unit 207. The second controller 102 includes a CPU and a storage including a ROM and a RAM, for example. The third controller 103 controls the heat shrinker 211 and the ultraviolet irradiator 212. The third controller 103 includes a CPU and a storage including a ROM and a RAM, for example. The second controller 102 and the third controller 103 may include, as a storage, an HDD that retains stored information even after the voltage is cut off.

The fourth controller 104 controls the cassette unit 202 and the lift-up hand unit 203. The fourth controller 104 includes a CPU and a storage including a ROM and a RAM, for example. The fifth controller 105 controls the suction hand unit 204. The fifth controller 105 includes a CPU and a storage including a ROM and a RAM, for example. The fourth controller 104 and the fifth controller 105 may include, as a storage, an HDD that retains stored information even after the voltage is cut off, for example.

The sixth controller 106 controls the chuck table unit 12. The sixth controller 106 includes a CPU and a storage including a ROM and a RAM, for example. The seventh controller 107 controls the laser 13. The seventh controller 107 includes a CPU and a storage including a ROM and a RAM, for example. The eighth controller 108 controls the imager 14. The eighth controller 108 includes a CPU and a storage including a ROM and a RAM, for example. The sixth controller 106, the seventh controller 107, and the eighth controller 108 may include, as a storage, an HDD that retains stored information even after the voltage is cut off, for example.

The expansion control calculator 109 performs calculations regarding a process to expand the sheet member W2 based on the processing results of the first controller 101, the second controller 102, and the third controller 103. The expansion control calculator 109 includes a CPU and a storage including a ROM and a RAM, for example.

The handling control calculator 110 performs calculations regarding a process to move the wafer ring structure W based on the processing results of the fourth controller 104 and the fifth controller 105. The handling control calculator 110 includes a CPU and a storage including a ROM and a RAM, for example.

The dicing control calculator 111 performs calculations regarding a process to dice the wafer W1 based on the processing results of the sixth controller 106, the seventh controller 107, and the eighth controller 108. The dicing control calculator 111 includes a CPU and a storage including a ROM and a RAM, for example. The configuration of the dicing control calculator 111 is described in detail below.

The storage 112 stores programs for operating the dicing device 1 and the expanding device 2. The storage 112 includes a ROM, a RAM, and an HDD, for example.

### Semiconductor Chip Manufacturing Process

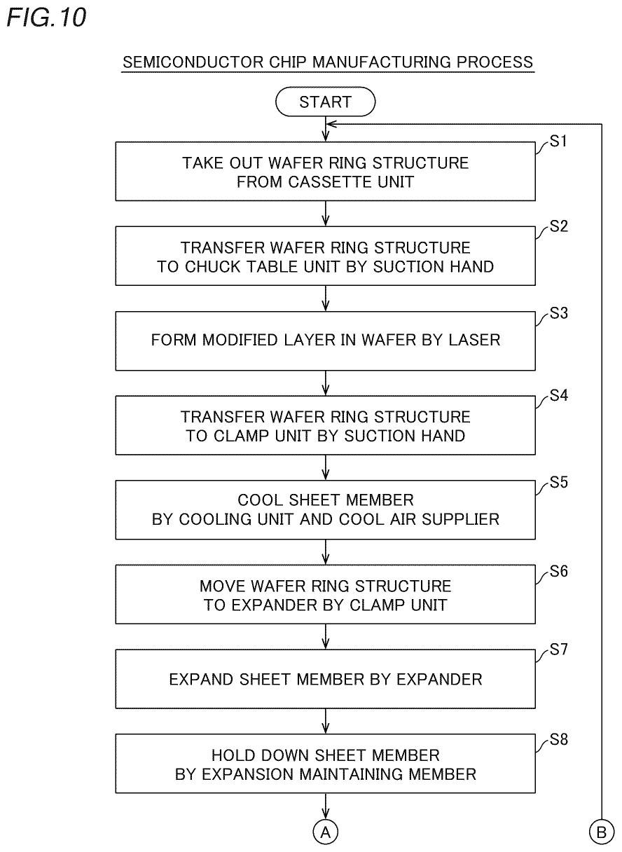

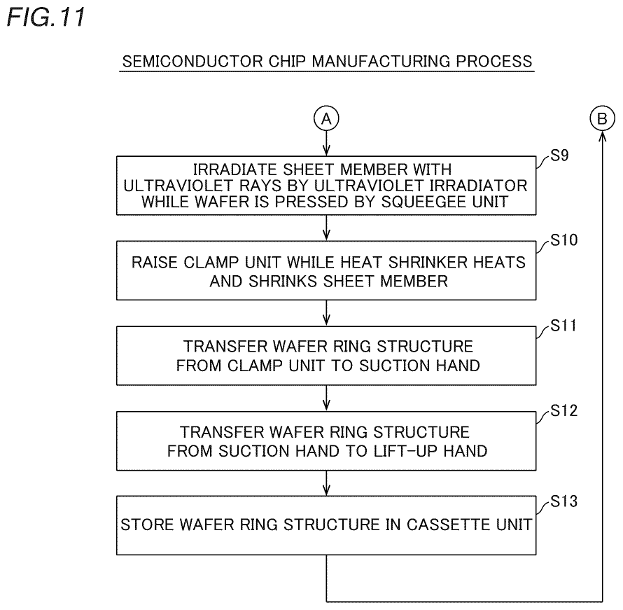

The overall operation of the semiconductor wafer processing apparatus 100 is described below with reference to FIGS. 10 and 11.

In step S1, the wafer ring structure W is taken out from the cassette unit 202. That is, after the wafer ring structure W stored in the cassette unit 202 is supported by the lift-up hand 203b, the lift-up hand 203b is moved in the Y1 direction by the Y-direction movement mechanism 203a such that the wafer ring structure W is taken out from the cassette unit 202. In step S2, the wafer ring structure W is transferred to the chuck table unit 12 of the dicing device 1 by the suction hand 204c. That is, the wafer ring structure W taken out from the cassette unit 202 is moved in the X2 direction by the X-direction movement mechanism 204a while being suctioned by the suction hand 204c. The wafer ring structure W that has been moved in the X2 direction is transferred from the suction hand 204c to the chuck table unit 12 and then held by the chuck table unit 12.

In step S3, a modified layer Wm is formed in the wafer W1 by the laser 13. In step S4, the wafer ring structure W including the wafer W1 in which the modified layer Wm has been formed is transferred to the clamp unit 214 by the suction hand 204c. In step S5, the sheet member W2 is cooled by the cool air supplier 206 and the cooling unit 207. That is, the wafer ring structure W held by the clamp unit 214 is moved (lowered) in the Z2 direction by the Z-direction movement mechanism 214b to contact the cooling unit 207, and the cool air supplier 206 supplies cool air from the Z1 direction side to cool the sheet member W2.

In step S6, the wafer ring structure W is moved to the expander 208 by the clamp unit 214. That is, the wafer ring structure W with the cooled sheet member W2 is moved in the Y1 direction by the Y-direction movement mechanism 214c while being held by the clamp unit 214. In step S7, the sheet member W2 is expanded by the expander 208. That is, the wafer ring structure W is moved in the Z2 direction by the Z-direction movement mechanism 214b while being held by the clamp unit 214. Then, the sheet member W2 contacts the expanding ring 281 and is expanded by being pulled by the expanding ring 281. Thus, the wafer W1 is divided along the dividing line (modified layer Wm).

In step S8, the expanded sheet member W2 is held down from the Z1 direction side by the expansion maintaining member 210. That is, the pressing ring 210a is moved (lowered) in the Z2 direction by the Z-direction movement mechanism 210d until it contacts the sheet member W2. Then, the process advances from a point A in FIG. 10 through a point A in FIG. 11 to step S9.

As shown in FIG. 11, in step S9, after the sheet member W2 is held down by the expansion maintaining member 210, the sheet member W2 is irradiated with ultraviolet rays Ut by the ultraviolet irradiator 212 while the wafer W1 is pressed by the squeegee unit 213. Thus, the wafer W1 is further divided by the squeegee unit 213. In addition, the adhesive strength of the sheet member W2 is reduced by the ultraviolet rays Ut emitted from the ultraviolet irradiator 212.

In step S10, while the heat shrinker 211 heats and shrinks the sheet member W2, the clamp unit 214 is raised. At this time, the intake 210c takes in air in the vicinity of the heated sheet member W2. In step S11, the wafer ring structure W is transferred from the clamp unit 214 to the suction hand 204c. That is, the wafer ring structure W is moved in the Y2 direction by the Y-direction movement mechanism 214c while being held by the clamp unit 214. Then, the wafer ring structure W is suctioned by the suction hand 204c after the holding by the clamp unit 214 is released on the Z1 direction side of the cooling unit 207.

In step S12, the wafer ring structure W is transferred to the lift-up hand 203b by the suction hand 204c. In step S13, the wafer ring structure W is stored in the cassette unit 202. That is, the wafer ring structure W supported by the lift-up hand 203b is moved in the Y1 direction by the Y-direction movement mechanism 203a to be stored in the cassette unit 202. Thus, the process performed on one wafer ring structure W is terminated. Then, the process returns from a point B in FIG. 11 through a point B in FIG. 10 to step S1.

### Detailed Configuration of Chuck Table Unit, Laser, and Imager

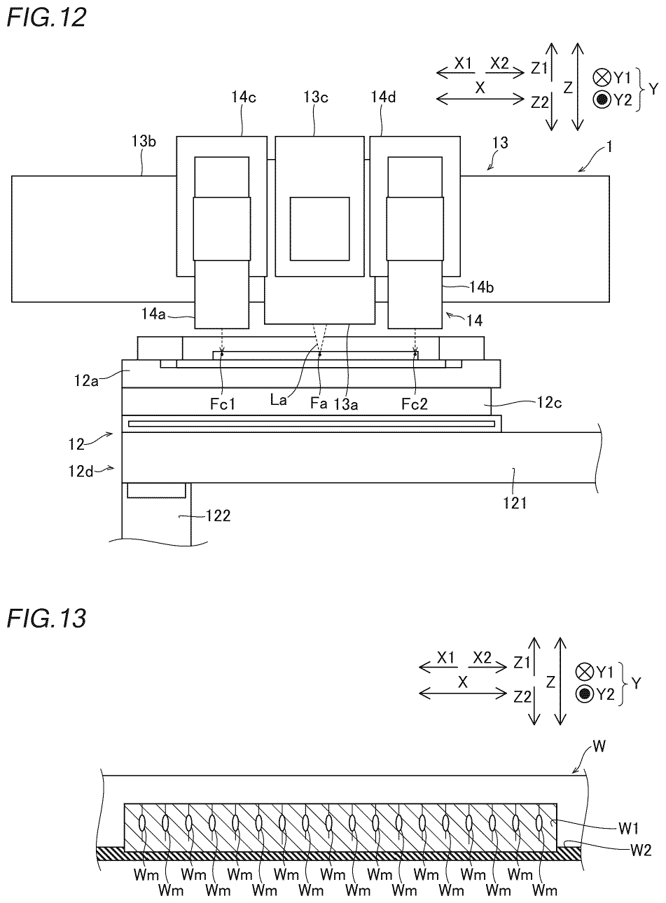

The detailed configuration of the chuck table unit 12, the laser 13, and the imager 14 of the dicing device 1 is now described with reference to FIGS. 12 to 16.

The chuck table unit 12 moves the wafer W1 including the plurality of semiconductor chips Ch (see FIG. 14) in at least one of the X direction (first direction in the horizontal direction) or the Y direction (second direction perpendicular to the first direction) and rotates the wafer W1, while holding the wafer W1. Specifically, the chuck table unit 12 includes the suction unit 12a, the clamps 12b, the rotation mechanism 12c, and the table movement mechanism 12d. The table movement mechanism 12d includes the X-direction movement mechanism 121 and the Y-direction movement mechanism 122.

### Laser

As shown in FIGS. 12 and 13, the laser 13 emits the laser beam La to the wafer W1 that moves or rotates while being held by the chuck table unit 12 in order to dice the wafer W1 into the plurality of semiconductor chips Ch. In the dicing performed by the dicing device 1 according to the first embodiment, the wafer W1 is not cut into the plurality of semiconductor chips Ch with the laser beam La, but the modified layer Wm is formed in the wafer W1 with the laser beam La, and then the wafer W1 is divided along the modified layer Wm.

Specifically, the laser 13 includes the laser irradiator 13a, the mounting member 13b, and the Z-direction movement mechanism 13c. The Z-direction movement mechanism 13c is a mechanism for moving (raising and lowering) the laser irradiator 13a in the Z1 direction and the Z2 direction to adjust the height position of the laser focus Fa of the laser beam La. At the laser focus Fa, the wafer W1 is burned by the heat of the condensed laser beam La such that the modified layer Wm is formed by modifying the inside along the dividing line.

### Imager

As shown in FIGS. 14 and 15, the imager 14 images a plurality of alignment marks Ar of the plurality of semiconductor chips Ch provided on the wafer W1. The alignment marks Ar are provided on the side (back side) of the wafer W1 closer to the sheet member W2.

The imager 14 includes the high-resolution camera 14a, the wide-angle camera 14b, the Z-direction movement mechanism 14c, and the Z-direction movement mechanism 14d. The Z-direction movement mechanism 14c is a mechanism for moving (raising and lowering) the high-resolution camera 14a in the upward-downward direction to adjust the imaging focus Fc1. The Z-direction movement mechanism 14d is a mechanism for moving (raising and lowering) the wide-angle camera 14b in the upward-downward direction to adjust the imaging focus Fc2. The high-resolution camera 14a and the wide-angle camera 14b are near-infrared imaging cameras.

The wafer W1 is a silicon wafer made of silicon, and thus it absorbs light having wavelengths other than infrared light. Thus, light other than infrared light reflected at the alignment marks Ar provided on the side of the wafer W1 closer to the sheet member W2 is absorbed by the wafer W1. Therefore, near-infrared imaging cameras are used as the high-resolution camera 14a and the wide-angle camera 14b in order to image near-infrared light reflected at the alignment marks Ar provided on the side of the wafer W1 closer to the sheet member W2 and transmitted through the wafer W1. Even when the alignment marks Ar are provided on the side of the wafer W1 opposite to the sheet member W2, it is possible to image infrared light reflected at the alignment marks Ar, and thus it is possible to image the alignment marks Ar by the high-resolution camera 14a and the wide-angle camera 14b. Thus, regardless of whether the alignment marks Ar are provided on the side of the wafer W1 closer to the sheet member W2 or on the side of the wafer W1 opposite to the sheet member W2, the alignment marks Ar can be imaged by the high-resolution camera 14a and the wide-angle camera 14b.

### Height Meter

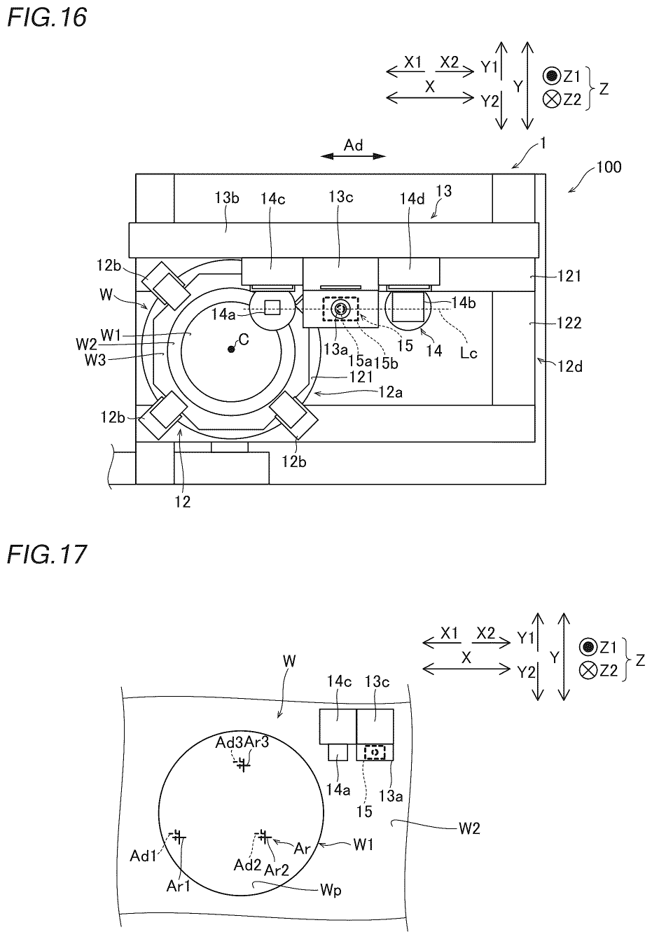

As shown in FIGS. 15 and 16, the dicing device 1 includes a height meter 15. The height meter 15 measures the height position of a surface of the wafer W1. The height meter 15 emits a laser beam Lm that is focused toward a focal point, acquires the diameter of the laser beam Lm on the wafer W1, and measures the height position of the surface of the wafer W1 based on the acquired diameter of the laser beam Lm. The height position of the surface of the wafer W1 refers to the position in the Z1 direction from the upper end surface of the base 11, with the upper end surface of the base 11 as a reference.

Specifically, the height meter 15 includes a laser emitter 15a and an imager 15b. Unlike the laser irradiator 13a, the laser emitter 15a emits the laser beam Lm that does not burn the wafer W1. The laser beam Lm is visible spot light. The imager 15b includes a camera capable of imaging visible light. The imager 15b images the laser beam Lm on the wafer W1 by imaging the wafer W1. Thus, the diameter of the laser beam Lm on the wafer W1 is acquired. Therefore, the diameter of the laser beam Lm that is focused toward the focal point becomes smaller toward the focal point, and thus the height position of the surface of the wafer W1 is measured.

The laser irradiator 13a, the laser emitter 15a, and the imager 15b are arranged coaxially in the Z direction.

The high-resolution camera 14a, the wide-angle camera 14b, and the height meter 15 are linearly aligned in an Ad direction (X direction) in which a first alignment mark Ar1 (see FIG. 14) and a second alignment mark Ar2 (see FIG. 14) of the plurality of alignment marks Ar are aligned in the plan view. Specifically, the optical center of the high-resolution camera 14a, the optical center of the wide-angle camera 14b, the optical center of the laser emitter 15a, and the optical center of the imager 15b are aligned in a straight line Lc in the Ad direction (X direction) in the plan view. The Ad direction is an example of a “predetermined direction” in the claims.

### Detailed Configuration of Dicing Control Calculator

In the dicing device 1, positional adjustment of the wafer W1 in the horizontal direction (in the plan view) (planar alignment of the wafer W1) is performed in order to accurately emit the laser beam La to the wafer W1 from the laser irradiator 13a along the street Ws. Furthermore, the modified layer Wm is formed in the wafer W1 while the laser focus Fa of the laser beam La emitted from the laser irradiator 13a is adjusted (height alignment of the laser focus Fa) in order to form the modified layer Wm at a precise position in the wafer W1.

Therefore, as shown in FIG. 17, in the dicing device 1, the rotation angle of the wafer W1 by the rotation mechanism 12c, the movement amount of the wafer W1 by the X-direction movement mechanism 121, and the movement amount of the wafer W1 by the Y-direction movement mechanism 122 are acquired in the chuck table unit 12 in order to align actual positions of two alignment marks Ar of the plurality of alignment marks Ar imaged by the high-resolution camera 14a with preset positions of the two alignment marks Ar based on differences between the actual positions and the preset positions. Furthermore, a height plane Wp (see FIG. 25) of the wafer W1 is specified based on the height positions of three points on the surface of the wafer W1 acquired by the height meter 15.

On the wafer W1 in the plan view, the position of each of the plurality of alignment marks Ar in the X direction and the position of each of the plurality of alignment marks Ar in the Y direction are set in advance. In FIG. 17, for convenience, only the first alignment mark Ar1, the second alignment mark Ar2, and a third alignment mark Ar3 are shown among the plurality of actual alignment marks Ar provided on the wafer W1. In addition, a first alignment mark Ad1 at a preset position corresponding to the first alignment mark Ar1, a second alignment mark Ad2 at a preset position corresponding to the second alignment mark Ar2, and a third alignment mark Ar3 at a preset position corresponding to the third alignment mark Ar3 are shown. In FIG. 17, the high-resolution camera 14a and the height meter 15 are shown in a simplified manner.

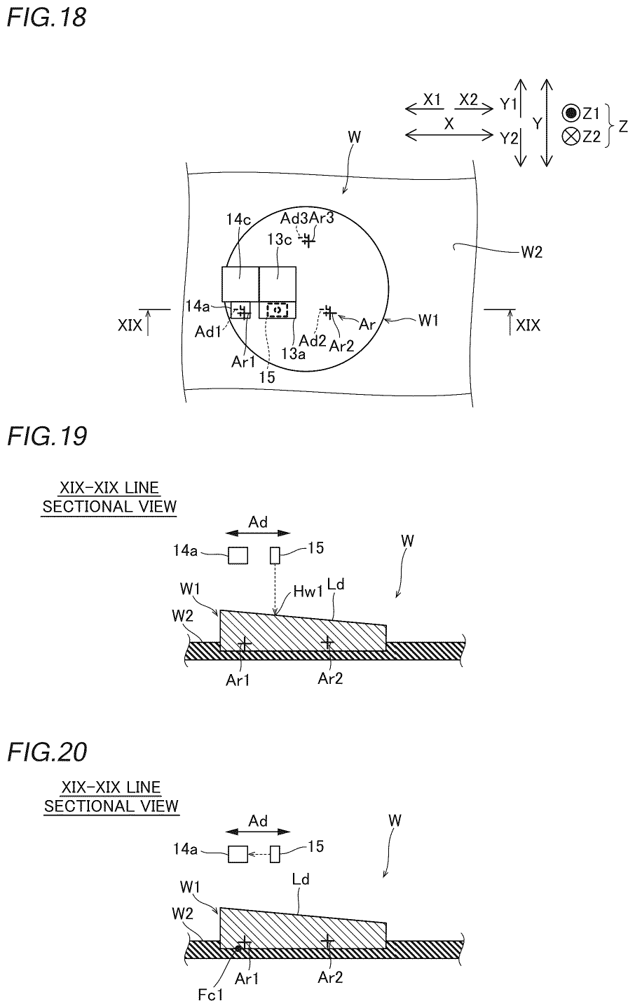

As shown in FIGS. 18 to 23, the dicing control calculator 111 according to the first embodiment controls the high-resolution camera 14a to image the plurality of alignment marks Ar while simultaneously controlling the height meter 15 to measure the height positions of the wafer W1.

Specifically, the dicing control calculator 111 performs a control to acquire whether or not the first alignment mark Ar1 and the second alignment mark Ar2 have been imaged when a straight portion Ld (see FIG. 22) passing through the first height position Hw1 and the second height position Hw2 of the wafer W1 is inclined outside an allowable range with respect to the horizontal direction, based on a difference Hd (see FIG. 22) between the first height position Hw1 (see FIG. 22) and the second height position Hw2 (see FIG. 22).

The first height position Hw1 is the height position of a portion of the wafer W1 shifted in the Ad direction from a first arrangement position at which the first alignment mark Ar1 is arranged, and the second height position Hw2 is the second height position Hw2 of a portion of the wafer W1 shifted in the Ad direction from a second arrangement position at which the second alignment mark Ar2 is arranged.

First, as shown in FIGS. 18 and 19, the dicing control calculator 111 performs a control to acquire the first height position Hw1 of the wafer W1 using the height meter 15. Furthermore, as shown in FIGS. 18 and 20, the dicing control calculator 111 controls the Z-direction movement mechanism 14c to adjust the imaging focus Fc1 of the high-resolution camera 14a arranged at a position at which the first alignment mark Ar1 at the first arrangement position is imaged based on the first height position Hw1. At this time, the imaging focus Fc1 is set based on the first height position Hw1 of the portion of the wafer W1 shifted in the Ad direction from the first arrangement position, not the first arrangement position. That is, the imaging focus Fc1 is not suitable as the imaging focus Fc1 for imaging the first alignment mark Ar1 unless the height position of the wafer W1 at the first arrangement position and the first height position Hw1 of the portion of the wafer W1 shifted in the Ad direction from the first arrangement position are substantially the same as each other (within an allowable range (within a tolerance)).

Thus, as shown in FIGS. 18 to 20, the dicing control calculator 111 performs a control to image the first alignment mark Ar1 after adjusting, using the Z-direction movement mechanism 14c, the imaging focus Fc1 of the high-resolution camera 14a arranged at the position at which the first alignment mark Ar1 at the first arrangement position is imaged based on the first height position Hw1 of the wafer W1.

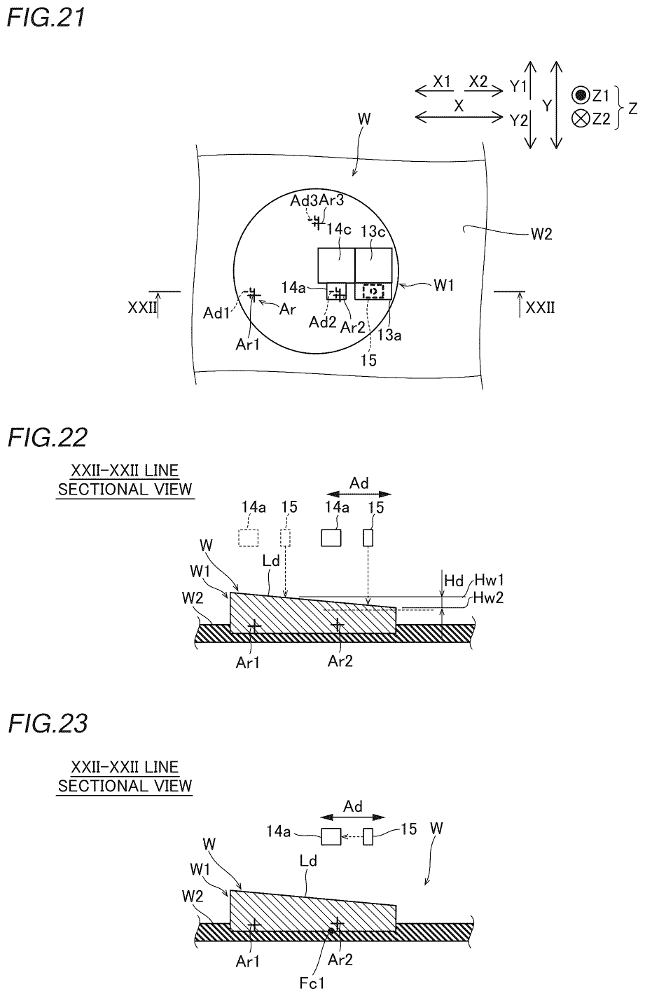

As shown in FIGS. 21 and 22, the dicing control calculator 111 performs a control to acquire the second height position Hw2 of the wafer W1 using the height meter 15. As shown in FIGS. 22 and 23, the dicing control calculator 111 controls the Z-direction movement mechanism 14c to adjust the imaging focus Fc1 of the high-resolution camera 14a arranged at a position at which the second alignment mark Ar2 at the second arrangement position is imaged based on the second height position Hw2. At this time, the imaging focus Fc1 is set based on the second height position Hw2 of the portion of the wafer W1 shifted in the Ad direction from the second arrangement position, not the second arrangement position. That is, the imaging focus Fc1 is not suitable as the imaging focus Fc1 for imaging the second alignment mark Ar2 unless the height position of the wafer W1 at the second arrangement position and the second height position Hw2 of the portion of the wafer W1 shifted in the Ad direction from the second arrangement position are substantially the same as each other (within an allowable range (with a tolerance)).

Thus, as shown in FIGS. 21 to 23, the dicing control calculator 111 performs a control to image the second alignment mark Ar2 after adjusting, using the Z-direction movement mechanism 14c, the imaging focus Fc1 of the high-resolution camera 14a arranged at the position at which the second alignment mark Ar2 at the second arrangement position is imaged based on the second height position Hw2 of the wafer W1.

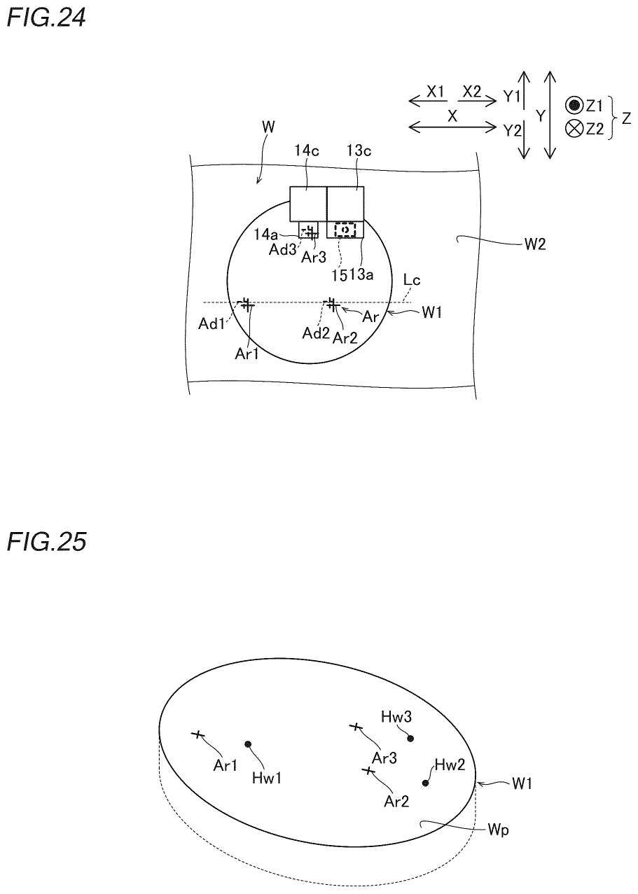

As shown in FIGS. 24 and 25, the dicing control calculator 111 performs a control to specify the height plane Wp of the wafer W1 based on the first height position Hw1, the second height position Hw2, and a third height position Hw3 measured by the height meter 15 at the arrangement position of the third alignment mark Ar3 that is not on the straight line Lc extending in the Ad direction.

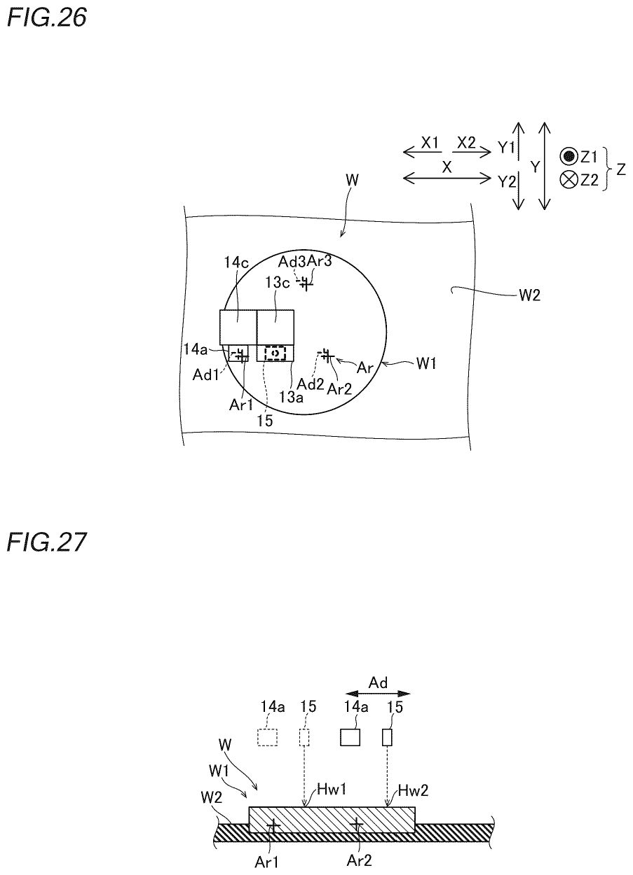

When the difference Hd between the first height position Hw1 and the second height position Hw2 is outside an allowable range, the dicing control calculator 111 performs a control to acquire the third alignment mark Ar3 imaged by the high-resolution camera 14a with the imaging focus Fc1 adjusted based on the specified height plane Wp. As shown in FIGS. 25 and 26, the dicing control calculator 111 performs a control to enable the positional adjustment of the wafer W1 in the horizontal direction based on the first alignment mark Ar1 (or the second alignment mark Ar2) imaged by the high-resolution camera 14a with the imaging focus Fc1 adjusted based on the specified height plane Wp.

Thus, the dicing control calculator 111 performs a control to acquire the positions of two alignment marks, the first alignment mark Ar1 (or the second alignment mark Ar2) and the third alignment mark Ar3, which are imaged with the imaging focus Fc1 of the high-resolution camera 14a adjusted, among the plurality of alignment marks Ar by moving the high-resolution camera 14a in the upward-downward direction using the Z-direction movement mechanism 14c to adjust the imaging focus Fc1 in order to adjust the position of the wafer W1 in the horizontal direction.

As shown in FIGS. 24 and 27, when the difference between the first height position Hw1 and the second height position Hw2 is within the allowable range, the dicing control calculator 111 controls the height meter 15 to measure the third height position Hw3 without imaging the third alignment mark Ar3 at the arrangement position of the third alignment mark Ar3 using the high-resolution camera 14a.

The dicing control calculator 111 performs a control to acquire the positions of two alignment marks Ar, the first alignment mark Ar1 and the second alignment mark Ar2, which are imaged with the imaging focus Fc1 of the high-resolution camera 14a adjusted, among the plurality of alignment marks Ar in order to adjust the position of the wafer W1 in the horizontal direction.

After the process described above, the dicing control calculator 111 controls the rotation mechanism 12c, the X-direction movement mechanism 121, and the Y-direction movement mechanism 122 of the chuck table unit 12 to perform planar alignment of the wafer W1. Accordingly, the planar alignment of the wafer W1 is performed, and thus it becomes possible to accurately emit the laser beam La from the laser irradiator 13a along the street Ws.

The dicing control calculator 111 performs a control to emit, to the wafer W1, the laser beam La with the laser focus Fa adjusted while simultaneously adjusting, using the Z-direction movement mechanism 13c, the height position of the laser irradiator 13a based on the height plane Wp of the wafer W1 specified based on the height positions of three points on the wafer W1 measured by the height meter 15. That is, the dicing control calculator 111 performs a control to emit the laser beam La with the position of the laser focus Fa adjusted in the Z direction based on the height plane Wp of the wafer W1 based on the height positions measured by the height meter 15 when the laser beam La is emitted from the laser irradiator 13a. Accordingly, height alignment of the laser focus Fa is performed, and thus the modified layer Wm can be formed at an accurate position in the wafer W1.

Such planar alignment of the wafer W1 and height alignment of the laser focus Fa are performed at a predetermined time set by a user, such as before the modified layer Wm is formed by the laser beam La in the wafer W1 of the first wafer ring structure W in the semiconductor wafer processing apparatus 100.

In the process described above by the dicing control calculator 111, an example has been shown in which the plurality of alignment marks Ar are imaged using the high-resolution camera 14a, but the positions of the alignment marks Ar to be imaged may be specified using the wide-angle camera 14b, and then the alignment marks Ar to be imaged may be imaged using the high-resolution camera 14a.

### Alignment Information Acquisition Process

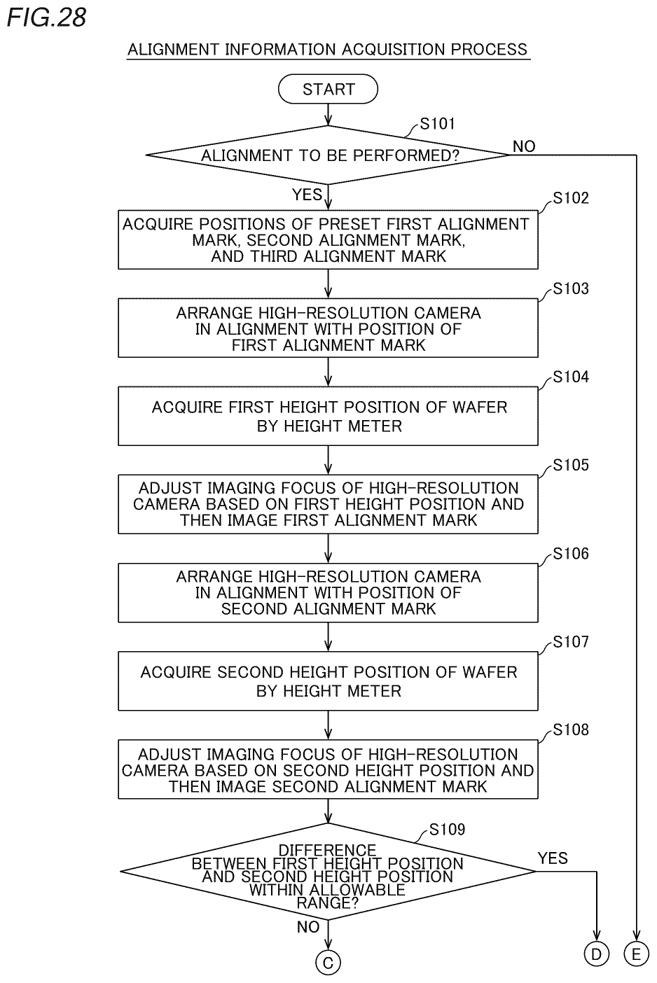

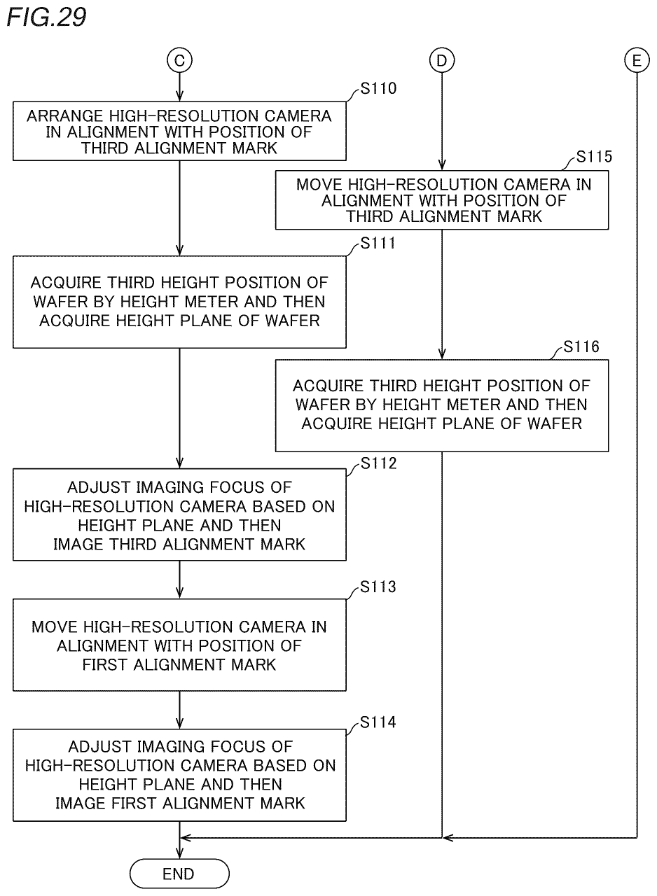

An alignment information acquisition process using the dicing control calculator 111 of the semiconductor wafer processing apparatus 100 is described below with reference to FIGS. 28 and 29.

In step S101, it is determined whether or not alignment is to be performed. That is, it is determined whether or not a predetermined case set by the user is present, such as whether or not the modified layer Wm is to be formed by the laser beam La in the wafer W1 of the first wafer ring structure W in the semiconductor wafer processing apparatus 100 such that it is determined whether or not planar alignment of the wafer W1 and height alignment of the laser focus Fa are to be performed. When the alignments are to be performed, it is necessary to acquire alignment information required for planar alignment of the wafer W1 and alignment information required for height alignment of the laser focus Fa, and thus the process advances to step S102. When the alignments are not to be performed, the process advances through a point E in FIG. 28 and a point E in FIG. 29, and the alignment information acquisition process is terminated.

In step S102, the positions of the preset first alignment mark Ad1, second alignment mark Ad2, and third alignment mark Ad3 are acquired. In step S103, the high-resolution camera 14a is arranged in alignment with the position of the first alignment mark Ad1 by moving the wafer W1 using the chuck table unit 12. In step S104, the first height position Hw1 of the wafer W1 is acquired by the height meter 15. Step S104 is a step in which the height meter 15 measures the height position of the surface of the wafer W1.

In step S105, the imaging focus Fc1 of the high-resolution camera 14a is adjusted based on the first height position Hw1, and then the actual first alignment mark Ar1 on the wafer W1 is imaged. Step S105 is a step in which the imager 14 images the plurality of alignment marks Ar of the plurality of semiconductor chips Ch provided on the wafer W1.

In step S106, the high-resolution camera 14a is arranged in alignment with the position of the second alignment mark Ad2 by moving the wafer W1 using the chuck table unit 12. In step S107, the second height position Hw2 of the wafer W1 is acquired by the height meter 15. Step S107 is a step in which the height meter 15 measures the height position of the surface of the wafer W1.

In step S108, the imaging focus Fc1 of the high-resolution camera 14a is adjusted based on the second height position Hw2, and then the actual second alignment mark Ar2 on the wafer W1 is imaged. Step S108 is a step in which the imager 14 images the plurality of alignment marks Ar of the plurality of semiconductor chips Ch provided on the wafer W1.

In step S109, it is determined whether or not the difference Hd between the first height position Hw1 and the second height position Hw2 is within the allowable range. When the difference Hd between the first height position Hw1 and the second height position Hw2 is within the allowable range, the process advances to step S115 through a point D in FIG. 28 and a point D in FIG. 29. When the difference Hd between the first height position Hw1 and the second height position Hw2 is outside the allowable range, the process advances to step S110 through a point C in FIG. 28 and a point C in FIG. 29. First, a case in which the difference Hd between the first height position Hw1 and the second height position Hw2 is outside the allowable range is described.

In step S110, the high-resolution camera 14a is arranged in alignment with the position of the third alignment mark Ad3 by moving the wafer W1 using the chuck table unit 12. In step S111, the third height position Hw3 of the wafer W1 is acquired by the height meter 15, and then the height plane Wp of the wafer W1 is acquired. Step S110 is a step in which the height meter 15 measures the height position of the surface of the wafer W1.

In step S112, the imaging focus Fc1 of the high-resolution camera 14a is adjusted based on the height plane Wp, and then the actual third alignment mark Ar3 on the wafer W1 is imaged. Step S110 is a step in which the imager 14 images the plurality of alignment marks Ar of the plurality of semiconductor chips Ch provided on the wafer W1.

In step S113, the high-resolution camera 14a is arranged in alignment with the position of the first alignment mark Ad1 by moving the wafer W1 using the chuck table unit 12. In step S114, the imaging focus Fc1 of the high-resolution camera 14a is adjusted based on the height plane Wp, and then the actual first alignment mark Ar1 on the wafer W1 is imaged. After step S114, the alignment information acquisition process is terminated. Next, a case in which the difference Hd between the first height position Hw1 and the second height position Hw2 is within the allowable range is described.

In step S115, the high-resolution camera 14a is arranged in alignment with the position of the third alignment mark Ad3 by moving the wafer W1 using the chuck table unit 12. In step S116, the third height position Hw3 of the wafer W1 is acquired by the height meter 15, and then the height plane Wp of the wafer W1 is acquired. After step S116, the alignment information acquisition process is terminated.

Then, after the alignment information acquisition process in a semiconductor chip manufacturing method (semiconductor chip manufacturing process described above), which is a manufacturing method for manufacturing the semiconductor chip Ch, is terminated, the dicing control calculator 111 performs a step of forming the modified layer Wm in the wafer W1, the position of which in the horizontal direction has been adjusted based on the plurality of alignment marks Ar imaged by the imager 14, by the laser beam La emitted from the laser irradiator 13a with the laser focus Fa of the laser beam La adjusted based on the height position of the surface of the wafer W1 measured by the height meter 15. Furthermore, the expansion control calculator 109 performs a step of expanding the sheet member W2 to which the wafer W1 has been attached in order to divide the wafer W1 into the plurality of semiconductor chips Ch along the modified layer Wm.

The semiconductor chip Ch manufactured by such a semiconductor chip manufacturing method is manufactured by the dicing device 1 including the imager 14 to image the plurality of alignment marks Ar of the plurality of semiconductor chips Ch provided on the wafer W1, and the height meter 15 to measure the height position of the surface of the wafer W1.

### Advantageous Effects of First Embodiment

According to the first embodiment, the following advantageous effects are achieved.

According to the first embodiment, as described above, the dicing device 1 includes the imager 14 to image the plurality of alignment marks Ar of the plurality of semiconductor chips Ch on the wafer W1, and the height meter 15 to measure the height position of the surface of the wafer W1. Accordingly, based on the alignment marks Ar imaged by the imager 14, the wafer W1 is moved and/or rotated by the chuck table unit 12 such that the position of the wafer W1 in the horizontal direction can be adjusted. Furthermore, the height position of the surface of the wafer W1 can be acquired based on the height position measured by the height meter 15, and thus the focus of the laser beam La emitted from the laser irradiator 13a on the wafer W1 can be adjusted based on the height position of the surface of the wafer W1. Consequently, the position of the wafer W1 in the horizontal direction can be adjusted, and the focus of the laser beam La emitted from the laser irradiator 13a on the wafer W1 can be adjusted.

According to the first embodiment, as described above, the dicing device 1 includes the dicing control calculator 111 configured or programmed to control the imager 14 to image the plurality of alignment marks Ar while simultaneously controlling the height meter 15 to measure the height positions of the wafer W1. Accordingly, the height positions of the surface of the wafer W1 can be acquired at positions at which the alignment marks Ar are imaged by the imager 14, and thus as compared with a case in which the alignment marks Ar are imaged by the imager 14 at positions different from positions at which the height positions of the surface of the wafer W1 are acquired, an increase in the number of times that the wafer W1 is moved in the first direction and the second direction in the horizontal direction by the chuck table unit 12 can be reduced or prevented.

According to the first embodiment, as described above, the imager 14 includes the Z-direction movement mechanism 14c to move the high-resolution camera 14a in the upward-downward direction to adjust the imaging focus Fc1. The dicing control calculator 111 is configured or programmed to perform a control to acquire the positions of the two alignment marks Ar imaged with the imaging focus Fc1 of the high-resolution camera 14a adjusted among the plurality of alignment marks Ar by moving the high-resolution camera 14a in the upward-downward direction using the Z-direction movement mechanism 14c to adjust the imaging focus Fc1 in order to adjust the position of the wafer W1 in the horizontal direction. Accordingly, the two actual alignment marks Ar on the wafer W1 can be clearly imaged by the high-resolution camera 14a, and thus the two alignment marks Ar can be accurately identified from other configurations. Consequently, the position of the wafer W1 in the horizontal direction can be adjusted based on the two accurate alignment marks Ar, and thus the position of the wafer W1 in the horizontal direction can be accurately adjusted.

According to the first embodiment, as described above, the high-resolution camera 14a and the height meter 15 are linearly aligned in the Ad direction (predetermined direction) in which the first alignment mark Ar1 and the second alignment mark Ar2 among the plurality of alignment marks Ar are aligned. Accordingly, at a position at which the first alignment mark Ar1 is imaged by the high-resolution camera 14a, the height meter 15 can measure the height position shifted in the Ad direction (predetermined direction). Furthermore, at a position at which the second alignment mark Ar2 is imaged by the high-resolution camera 14a, the height meter 15 can measure the height position shifted in the Ad direction (predetermined direction). Thus, the inclination of the straight portion Ld passing through the two height positions on the wafer W1 with respect to the horizontal direction can be acquired. When the two height positions are measured, the first alignment mark Ar1 and the second alignment mark Ar2 are imaged in parallel such that information can be acquired to determine whether or not the first alignment mark Ar1 and the second alignment mark Ar2 have been imaged by the high-resolution camera 14a when the wafer W1 is excessively inclined and it is difficult to adjust the imaging focus Fc1 of the high-resolution camera 14a.

According to the first embodiment, as described above, the dicing control calculator 111 is configured or programmed to perform a control to acquire, based on the difference Hd between the first height position Hw1 of the portion of the wafer W1 shifted in the Ad direction (predetermined direction) from the first arrangement position at which the first alignment mark Ar1 is arranged and the second height position Hw2 of the portion of the wafer W1 shifted in the Ad direction (predetermined direction) from the second arrangement position at which the second alignment mark Ar2 is arranged, whether or not the first alignment mark Ar1 and the second alignment mark Ar2 have been imaged when the straight portion Ld passing through the first height position Hw1 and the second height position Hw2 of the wafer W1 is inclined outside the allowable range with respect to the horizontal direction. Accordingly, it is possible to identify whether or not the first alignment mark Ar1 and the second alignment mark Ar2 have been imaged by the high-resolution camera 14a when the straight portion Ld passing through the two height positions on the wafer W1 is excessively inclined, based on the difference Hd between the first height position Hw1 and the second height position Hw2. Consequently, it is possible to identify whether or not the first alignment mark Ar1 and the second alignment mark Ar2 have been imaged by the high-resolution camera 14a when the wafer W1 is excessively inclined such that it is difficult to adjust the imaging focus Fc1 of the imager 14.

According to the first embodiment, as described above, the dicing control calculator 111 is configured or programmed to perform a control to image the first alignment mark Ar1 after adjusting, using the Z-direction movement mechanism 14c, the imaging focus Fc1 of the high-resolution camera 14a arranged at the position at which the first alignment mark Ar1 at the first arrangement position is imaged based on the first height position Hw1 of the wafer W1, and to image the second alignment mark Ar2 after adjusting, using the Z-direction movement mechanism 14c, the imaging focus Fc1 of the high-resolution camera 14a arranged at the position at which the second alignment mark Ar2 at the second arrangement position is imaged based on the second height position Hw2 of the wafer W1. Accordingly, the imaging focus Fc1 of the high-resolution camera 14a arranged at the position at which the first alignment mark Ar1 at the first arrangement position is imaged is adjusted based on the first height position Hw1 of the portion of the wafer W1 shifted in the Ad direction (predetermined direction) from the first arrangement position at which the first alignment mark Ar1 is arranged, and thus it is difficult to image the first alignment mark Ar1 with the imaging focus Fc1 adjusted unless the surface of the wafer W1 is nearly horizontal. Furthermore, the imaging focus Fc1 of the high-resolution camera 14a arranged at the position at which the second alignment mark Ar2 at the second arrangement position is imaged is adjusted based on the second height position Hw2 of the portion of the wafer W1 shifted in the Ad direction (predetermined direction) from the second arrangement position at which the second alignment mark Ar2 is arranged, and thus it is difficult to image the second alignment mark Ar2 with the imaging focus Fc1 adjusted unless the surface of the wafer W1 is nearly horizontal. Thus, when the difference Hd between the first height position Hw1 and the second height position Hw2 is within the allowable range and the surface of the wafer W1 is nearly horizontal, the first alignment mark Ar1 and the second alignment mark Ar2 are imaged with the imaging focus Fc1 adjusted, and thus the position of the wafer W1 in the horizontal direction can be adjusted based on the first alignment mark Ar1 and the second alignment mark Ar2. Consequently, it is possible to prevent an imaging process for imaging alignment marks Ar other than the first alignment mark Ar1 and the second alignment mark Ar2 to be performed, and thus an increase in the processing time in the dicing device 1 can be reduced or prevented.

According to the first embodiment, as described above, the dicing control calculator 111 is configured or programmed to perform a control to specify the height plane Wp of the wafer W1 based on the first height position Hw1, the second height position Hw2, and the third height position Hw3 measured by the height meter 15 at the arrangement position of the third alignment mark Ar3 that is not on the straight line Lc extending in the Ad direction (predetermined direction). Accordingly, the imaging focus Fc1 of the high-resolution camera 14a for imaging the plurality of alignment marks Ar on the wafer W1 can be accurately adjusted based on the height plane Wp of the wafer W1, and thus the high-resolution camera 14a can clearly image the alignment marks Ar. Furthermore, the laser focus Fa of the laser beam La emitted from the laser irradiator 13a can be adjusted to a position according to the height plane Wp of the wafer W1 using the height plane Wp of the wafer W1, and thus an appropriate position on the wafer W1 can be processed by the laser beam.

According to the first embodiment, as described above, the dicing control calculator 111 is configured or programmed to, when the difference Hd between the first height position Hw1 and the second height position Hw2 is outside the allowable range, perform a control to enable the positional adjustment of the wafer W1 in the horizontal direction based on the third alignment mark Ar3 imaged by the high-resolution camera 14a with the imaging focus Fc1 adjusted based on the specified height plane Wp, and the first alignment mark Ar1 or the second alignment mark Ar2 imaged by the high-resolution camera 14a with the imaging focus Fc1 adjusted based on the specified height plane Wp. Accordingly, the third alignment mark Ar3 and the first alignment mark Ar1 or the second alignment mark Ar2 can be imaged by the high-resolution camera 14a with the imaging focus Fc1 accurately adjusted based on the height plane Wp of the wafer W1, and thus the third alignment mark Ar3 and the first alignment mark Ar1 or the second alignment mark Ar2 can be clearly imaged. Consequently, the position of the third alignment mark Ar3 and the position of the first alignment mark Ar1 or the position of the second alignment mark Ar2 can be reliably acquired, and thus the chuck table unit 12 moves and/or rotates the wafer W1 such that the positional adjustment of the wafer W1 in the horizontal direction is enabled.

According to the first embodiment, as described above, the dicing control calculator 111 is configured or programmed to control the height meter 15 to measure the third height position Hw3 without imaging the third alignment mark Ar3 at the arrangement position of the third alignment mark Ar3 using the high-resolution camera 14a when the difference Hd between the first height position Hw1 and the second height position Hw2 is within the allowable range. Accordingly, even when the third alignment mark Ar3 is not imaged, the position of the wafer W1 in the horizontal direction can be adjusted based on the first alignment mark Ar1 and the second alignment mark Ar2, and thus the processing time in the dicing device 1 can be reduced by the amount of time required to image the third alignment mark Ar3.

According to the first embodiment, as described above, the dicing device 1 includes the Z-direction movement mechanism 13c to move the laser irradiator 13a in the upward-downward direction to adjust the laser focus Fa of the laser beam La. The dicing control calculator 111 is configured or programmed to perform a control to emit, to the wafer W1, the laser beam La with the laser focus Fa adjusted while simultaneously adjusting, using the Z-direction movement mechanism 13c, the height position of the laser irradiator 13a based on the height plane Wp of the wafer W1 specified based on the height positions of the three points on the wafer W1 measured by the height meter 15. Accordingly, the height position of the laser irradiator 13a is adjusted by the Z-direction movement mechanism 13c based on the height plane Wp of the wafer W1 such that the laser focus Fa of the laser beam La emitted from the laser irradiator 13a can be adjusted to an appropriate position according to the height plane Wp of the wafer W1, and thus as compared with a case in which the chuck table unit 12 including the mechanism to move and rotate the wafer W1 in the first direction and the second direction in the horizontal direction is moved in the upward-downward direction, an increase in the driving force of a drive source required for the lifting mechanism can be reduced or prevented. Consequently, a relatively small drive source can be used for the lifting mechanism, and thus an increase in the size of the dicing device 1 can be reduced or prevented.

According to the first embodiment, as described above, the imager 14 includes an infrared camera. Accordingly, it is possible to image infrared light reflected by the alignment marks Ar provided on the wafer W1 and transmitted through the wafer W1, and thus even when the alignment marks Ar are provided on the side of the wafer W1 closer to the sheet member W2, it is possible to image the alignment marks Ar provided on the wafer W1. Furthermore, even when the alignment marks Ar are provided on the side of the wafer W1 opposite to the sheet member W2, it is possible to image the infrared light reflected by the alignment marks Ar, and thus the alignment marks Ar provided on the wafer W1 can be imaged. Consequently, the alignment marks Ar can be imaged both when the alignment marks Ar are provided on the side of the wafer W1 closer to the sheet member W2 and when the alignment marks Ar are provided on the side of the wafer W1 opposite to the sheet member W2.

According to the first embodiment, as described above, the imager 14 includes the wide-angle camera 14b and the high-resolution camera 14a. The wide-angle camera 14b has a wider angle of view than the high-resolution camera 14a. The high-resolution camera 14a has a higher resolution than the wide-angle camera 14b. Accordingly, when a plurality of wafers W1 of the same type are processed in the dicing device 1, the accuracy of positioning the wafer W1 in the horizontal direction has not been confirmed when the first wafer W1 is processed. Thus, the wide-angle camera 14b capable of imaging the wafer W1 at a wider angle of view is used when the first alignment mark Ar1 and the second alignment mark Ar2 are imaged such that the first alignment mark Ar1 and the second alignment mark Ar2 can be more reliably imaged. Furthermore, when a plurality of wafers W1 of the same type are processed in the dicing device 1, the first alignment mark Ar1 and the second alignment mark Ar2 are imaged a plurality of times by the wide-angle camera 14b until the exact positions of the first alignment mark Ar1 and the second alignment mark Ar2 can be acquired, and then the first alignment mark Ar1 and the second alignment mark Ar2 can be imaged by the high-resolution camera 14a. Consequently, after it becomes possible to reliably image the first alignment mark Ar1 and the second alignment mark Ar2, the first alignment mark Ar1 and the second alignment mark Ar2 can be clearly imaged.

According to the first embodiment, as described above, the manufacturing method for the semiconductor chip Ch includes a step of imaging, by the imager 14, the plurality of alignment marks Ar of the plurality of semiconductor chips Ch on the wafer W1. Furthermore, the manufacturing method for the semiconductor chip Ch includes a step of measuring, by the height meter 15, the height position of the surface of the wafer W1. Moreover, the manufacturing method for the semiconductor chip Ch includes a step of emitting the laser beam La to the wafer W1 from the laser irradiator 13a operable to emit the laser beam La in order to dice the wafer W1 into the plurality of semiconductor chips Ch. Accordingly, the position of the wafer W1 in the horizontal direction can be adjusted based on the alignment marks Ar imaged by the imager 14. Furthermore, the height position of the surface of the wafer W1 can be acquired based on the height position measured by the height meter 15, and thus the laser focus Fa of the laser beam La emitted from the laser irradiator 13a on the wafer W1 can be adjusted based on the height position of the surface of the wafer W1. Consequently, it is possible to obtain the semiconductor chip manufacturing method that enables the position of the wafer W1 in the horizontal direction to be adjusted and the laser focus Fa of the laser beam La emitted from the laser irradiator 13a on the wafer W1 to be adjusted.

According to the first embodiment, as described above, the semiconductor chip Ch is manufactured by the dicing device 1 including the imager 14 to image the plurality of alignment marks Ar of the plurality of semiconductor chips Ch on the wafer W1, and the height meter 15 to measure the height position of the surface of the wafer W1. Accordingly, based on the alignment marks Ar imaged by the imager 14, the wafer W1 is moved and/or rotated by the chuck table unit 12 such that the position of the wafer W1 in the horizontal direction can be adjusted. Furthermore, the height position of the surface of the wafer W1 can be acquired based on the height position measured by the height meter 15, and thus the laser focus Fa of the laser beam La emitted from the laser irradiator 13a on the wafer W1 can be adjusted based on the height position of the surface of the wafer W1. Consequently, it is possible to obtain the semiconductor chip Ch manufactured by the dicing device 1 capable of adjusting the position of the wafer W1 in the horizontal direction and adjusting the laser focus Fa of the laser beam La emitted from the laser irradiator 13a on the wafer W1.

### Second Embodiment

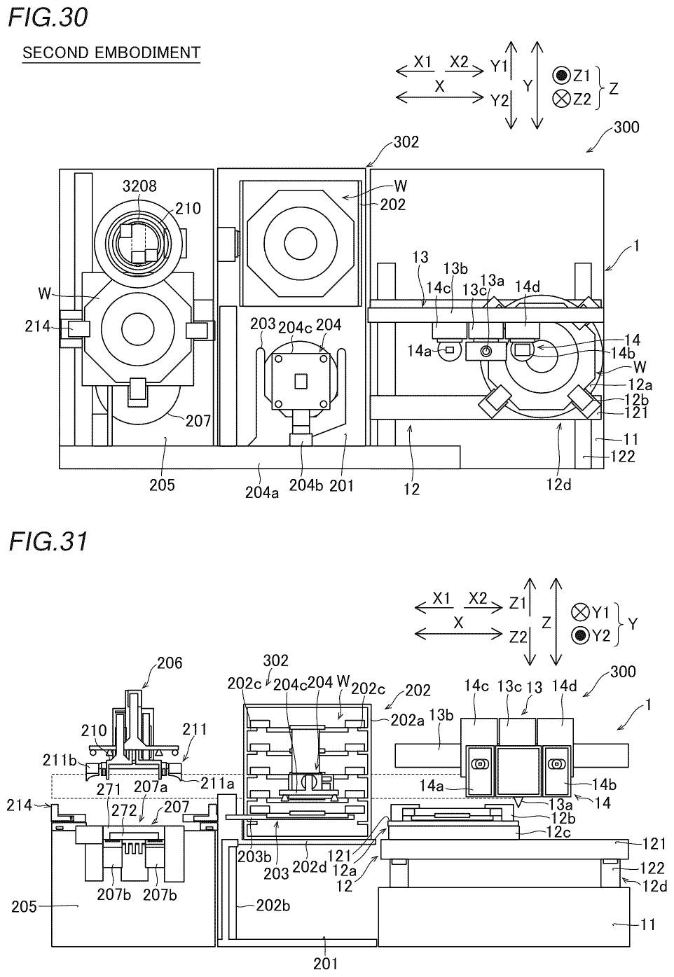

The configuration of a semiconductor wafer processing apparatus 300 according to a second embodiment is now described with reference to FIGS. 30 to 35. In the second embodiment, a squeegee unit 3213 is arranged outside an expanding ring 3281, unlike the first embodiment. In the second embodiment, detailed description of the same or similar configurations as those of the first embodiment is omitted.

### Semiconductor Wafer Processing Apparatus

As shown in FIGS. 30 and 31, the semiconductor wafer processing apparatus 300 is an apparatus that processes a wafer W1 provided on a wafer ring structure W.

The semiconductor wafer processing apparatus 300 includes a dicing device 1 and an expanding device 302. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 302 are aligned is defined as an X direction, a direction from the dicing device 1 toward the expanding device 302 in the X direction is defined as an X1 direction, and a direction from the expanding device 302 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser having a wavelength transmissive to the wafer W1 along a dividing line (street Ws) to form a modified layer Wm.

Specifically, the dicing device 1 includes a base 11, a chuck table unit 12, a laser 13, and an imager 14.

### Expanding Device

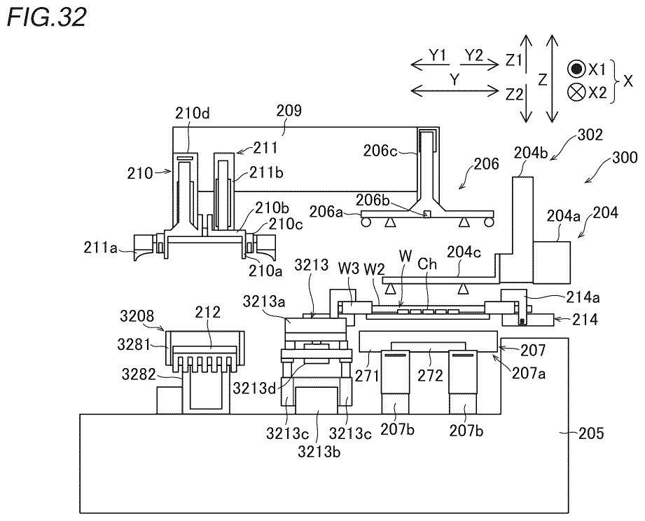

As shown in FIGS. 31 and 32, the expanding device 302 divides the wafer W1 to form a plurality of semiconductor chips Ch.

The expanding device 302 includes a base 201, a cassette unit 202, a lift-up hand unit 203, a suction hand unit 204, a base 205, a cool air supplier 206, a cooling unit 207, an expander 3208, a base 209, an expansion maintaining member 210, a heat shrinker 211, an ultraviolet irradiator 212, a squeegee unit 3213, and a clamp unit 214.

### Expander

The expander 3208 expands a sheet member W2 of the wafer ring structure W to divide the wafer W1 along the dividing line.

Specifically, the expander 3208 includes the expanding ring 3281 and a Z-direction movement mechanism 3282.

The expanding ring 3281 expands the sheet member W2 by supporting the sheet member W2 from the Z2 direction side. The expanding ring 3281 has a ring shape in a plan view. The Z-direction movement mechanism 3282 moves the expanding ring 3281 in the Z1 direction or the Z2 direction. The Z-direction movement mechanism 3282 includes a linear conveyor module, or a ball screw and a drive including a motor with an encoder, for example. The Z-direction movement mechanism 3282 is attached to the base 205.

### Squeegee Unit

The squeegee unit 3213 further divides the wafer W1 along the modified layer Wm by pressing the wafer W1 from the Z2 direction side after the sheet member W2 is expanded. Specifically, the squeegee unit 3213 includes a press 3213a, an X-direction movement mechanism 3213b, a Z-direction movement mechanism 3213c, and a rotation mechanism 3213d.

The press 3213a generates a bending stress in the wafer W1 to divide the wafer W1 along the modified layer Wm by being moved by the rotation mechanism 3213d and the X-direction movement mechanism 3213b while pressing the wafer W1 from the Z2 direction side via the sheet member W2 after being moved in the Z1 direction by the Z-direction movement mechanism 3213c. The press 3213a is a squeegee. The press 3213a is attached to an end of the rotation mechanism 3213d on the Z1 direction side. The Z-direction movement mechanism 3213c moves the rotation mechanism 3213d in the Z1 direction or the Z2 direction. The Z-direction movement mechanism 3213c includes a cylinder, for example. The Z-direction movement mechanism 3213c is attached to an end of the X-direction movement mechanism 3213b on the Z1 direction side. The X-direction movement mechanism 3213b includes a linear conveyor module, or a ball screw and a drive including a motor with an encoder, for example. The X-direction movement mechanism 3213b is attached to an end of the base 205 on the Z1 direction side.

In the squeegee unit 3213, the press 3213a divides the wafer W1 by being moved in the Y direction by the X-direction movement mechanism 3213b while pressing the wafer W1 from the Z2 direction side via the sheet member W2 after being moved in the Z1 direction by the Z-direction movement mechanism 3213c. Furthermore, in the squeegee unit 3213, after the press 3213a finishes moving in the Y direction, the press 3213a is rotated 90 degrees by the rotation mechanism 3213d. Moreover, in the squeegee unit 3213, the press 3213a divides the wafer W1 by being moved in the X direction by the X-direction movement mechanism 3213b while pressing the wafer W1 from the Z2 direction side via the sheet member W2 after being rotated 90 degrees.

### Control Configuration of Semiconductor Wafer Processing Apparatus

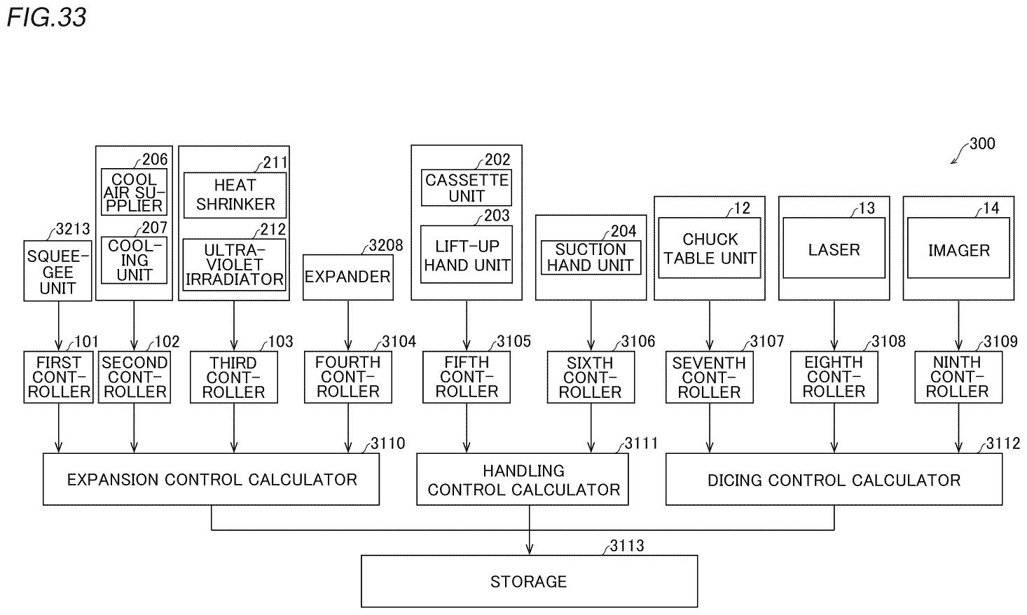

As shown in FIG. 33, the semiconductor wafer processing apparatus 300 includes a first controller 101, a second controller 102, a third controller 103, a fourth controller 3104, a fifth controller 3105, a sixth controller 3106, a seventh controller 3107, an eighth controller 3108, a ninth controller 3109, an expansion control calculator 3110, a handling control calculator 3111, a dicing control calculator 3112, and a storage 3113. The first controller 101, the second controller 102, the third controller 103, the fifth controller 3105, the sixth controller 3106, the seventh controller 3107, the eighth controller 3108, the ninth controller 3109, the expansion control calculator 3110, the handling control calculator 3111, the dicing control calculator 3112, and the storage 3113 have the same configurations as the first controller 101, the second controller 102, the third controller 103, the fourth controller 104, the fifth controller 105, the sixth controller 106, the seventh controller 107, the eighth controller 108, the expansion control calculator 109, the handling control calculator 110, the dicing control calculator 111, and the storage 112 according to the first embodiment, respectively, and thus description thereof is omitted.

The fourth controller 3104 controls the expander 3208. The fourth controller 3104 includes a CPU and a storage including a ROM and a RAM, for example. The fourth controller 3104 may include, as a storage, an HDD that retains stored information even after the voltage is cut off, for example.

### Semiconductor Chip Manufacturing Process

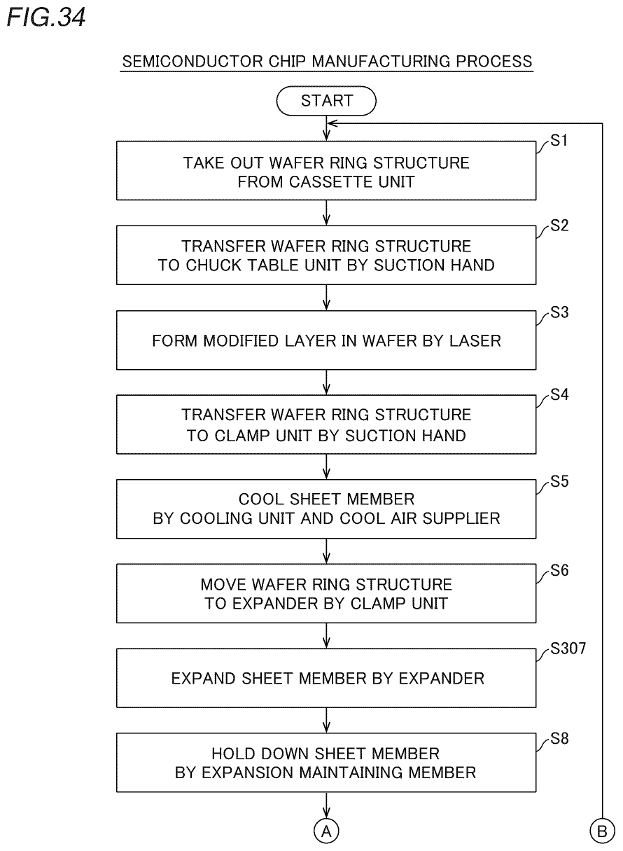

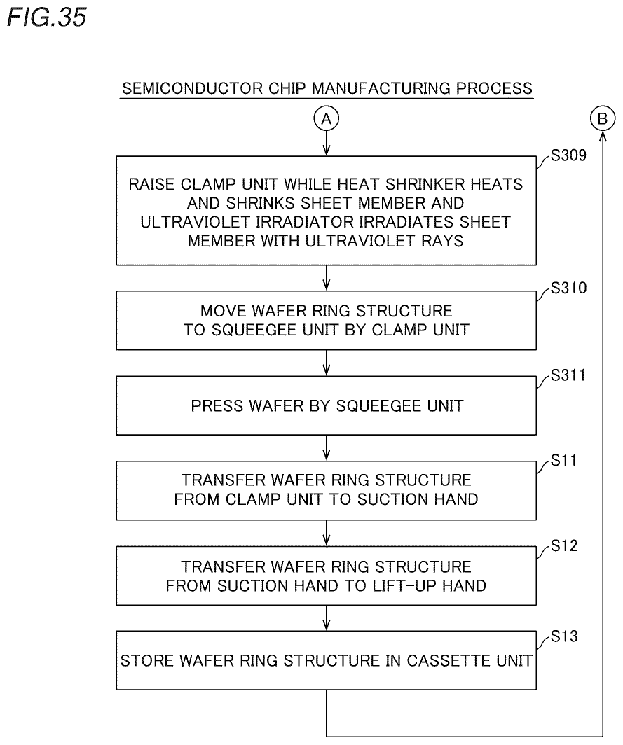

The overall operation of the semiconductor wafer processing apparatus 300 is described below with reference to FIGS. 34 and 35.

Process operations in step S1 to step S6, step S8, and step S11 are the same as the process operations in step S1 to step S6, step S8, and step S11 in the semiconductor chip manufacturing process according to the first embodiment, respectively, and thus description thereof is omitted.

In step S307, the sheet member W2 is expanded by the expander 3208. That is, the expanding ring 3281 is moved in the Z1 direction by the Z-direction movement mechanism 3282. The wafer ring structure W is moved in the Z2 direction by a Z-direction movement mechanism 214b while being held by the clamp unit 214. Then, the sheet member W2 is expanded by contacting the expanding ring 3281 and being pulled by the expanding ring 3281. Thus, the wafer W1 is divided along the dividing line (modified layer Wm).

As shown in FIG. 35, in step S309, while the heat shrinker 211 heats and shrinks the sheet member W2 and the ultraviolet irradiator 212 irradiates the sheet member W2 with ultraviolet rays Ut, the clamp unit 214 is raised. At this time, an intake 210c takes in air in the vicinity of the heated sheet member W2. In step S310, the wafer ring structure W is moved to the squeegee unit 3213 by the clamp unit 214. That is, the wafer ring structure W is moved in the Y2 direction by a Y-direction movement mechanism 214c while being held by the clamp unit 214.

In step S311, after the wafer ring structure W is moved to the squeegee unit 3213, the wafer W1 is pressed by the squeegee unit 3213. Thus, the wafer W1 is further divided by the squeegee unit 3213.

### Detailed Configuration of Dicing Control Calculator

The detailed configuration of the dicing control calculator 3112 is the same as the detailed configuration of the dicing control calculator 111 according to the first embodiment, and thus description thereof is omitted. The remaining configurations of the second embodiment are similar to those of the first embodiment, and thus description thereof is omitted.

### Advantageous Effects of Second Embodiment

According to the second embodiment, the following advantageous effects are achieved.

According to the second embodiment, similarly to the first embodiment, the dicing device 1 includes the imager 14 to image a plurality of alignment marks Ar of the plurality of semiconductor chips Ch provided on the wafer W1, and a height meter 15 to measure the height position of a surface of the wafer W1. Accordingly, the position of the wafer W1 in the horizontal direction can be adjusted, and the focus of a laser beam La emitted from a laser irradiator 13a on the wafer W1 can be adjusted. The remaining advantageous effects of the second embodiment are similar to those of the first embodiment, and thus description thereof is omitted.

### Modified Examples

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

For example, while the example in which the imager 14 and the height meter 15 are linearly aligned in the Ad direction (predetermined direction) in which the first alignment mark Ar1 and the second alignment mark Ar2 among the plurality of alignment marks are aligned has been shown in each of the aforementioned first and second embodiments, the present disclosure is not restricted to this. In the present disclosure, the imager and the height meter may not be aligned linearly in the predetermined direction.

While the example in which the high-resolution camera 14a and the wide-angle camera 14b (imager) are near-infrared imaging cameras has been shown in each of the aforementioned first and second embodiments, the present disclosure is not restricted to this. In the present disclosure, the imager may be a type of camera other than a near-infrared imaging camera.

While the example in which the imager 14 includes the high-resolution camera 14a (second camera) and the wide-angle camera 14b (first camera) has been shown in each of the aforementioned first and second embodiments, the present disclosure is not restricted to this. In the present disclosure, the imager may include either the high-resolution second camera or the wide-angle first camera.

While the example in which the high-resolution camera 14a and the wide-angle camera 14b as near-infrared imaging cameras image the alignment marks Ar provided on the side (back side) of the wafer W1 closer to the sheet member W2 has been shown in each of the aforementioned first and second embodiments, the present disclosure is not restricted to this. In the present disclosure, when the alignment marks are provided on the side (front side) of the wafer opposite to the sheet member, the alignment marks may be imaged by a visible light camera.

While the control process of the dicing control calculator 111 (3112: controller) is described, using the flowchart described in a manner driven by a flow in which processes are performed in order along a process flow for the convenience of illustration in each of the aforementioned first and second embodiments, the present disclosure is not restricted to this. In the present disclosure, the control process of the controller may be performed in an event-driven manner in which processes are performed on an event basis. In this case, the control process may be performed in a complete event-driven manner or in a combination of an event-driven manner and a manner driven by a flow.

What is claimed is:

1. A dicing device comprising:
a table configured to move a wafer including a plurality of semiconductor chips in at least one of a first direction in a horizontal direction or a second direction in the horizontal direction perpendicular to the first direction and rotate the wafer, while holding the wafer;
a laser irradiator configured to emit a laser beam to the wafer moved or rotated while being held by the table in order to dice the wafer into the plurality of semiconductor chips;
an imager configured to image a plurality of alignment marks of the plurality of semiconductor chips on the wafer; and
a height meter configured to measure a height position of a surface of the wafer.

2. The dicing device according to claim 1, further comprising:
a controller configured or programmed to control the imager to image the plurality of alignment marks while simultaneously controlling the height meter to measure height positions of the wafer.

3. The dicing device according to claim 2, wherein
the imager includes an imager lifting mechanism configured to move the imager in an upward-downward direction to adjust an imaging focus of the imager; and
the controller is configured or programmed to perform a control to acquire positions of two alignment marks imaged with the imaging focus of the imager adjusted among the plurality of alignment marks by moving the imager in the upward-downward direction using the imager lifting mechanism to adjust the imaging focus in order to adjust a position of the wafer in the horizontal direction.

4. The dicing device according to claim 3, wherein
the imager and the height meter are linearly aligned in a predetermined direction in which a first alignment mark and a second alignment mark among the plurality of alignment marks are aligned.

5. The dicing device according to claim 4, wherein
the controller is configured or programmed to perform a control to acquire, based on a difference between a first height position of a portion of the wafer shifted in the predetermined direction from a first arrangement position at which the first alignment mark is arranged and a second height position of a portion of the wafer shifted in the predetermined direction from a second arrangement position at which the second alignment mark is arranged, whether or not the first alignment mark and the second alignment mark have been imaged when a straight portion passing through the first height position and the second height position of the wafer is inclined outside an allowable range with respect to the horizontal direction.

6. The dicing device according to claim 5, wherein
the controller is configured or programmed to perform a control to image the first alignment mark after adjusting, using the imager lifting mechanism, the imaging focus of the imager at a position at which the first alignment mark at the first arrangement position is imaged based on the first height position of the wafer, and to image the second alignment mark after adjusting, using the imager lifting mechanism, the imaging focus of the imager at a position at which the second alignment mark at the second arrangement position is imaged based on the second height position of the wafer.

7. The dicing device according to claim 6, wherein
the controller is configured or programmed to perform a control to specify a height plane of the wafer based on the first height position, the second height position, and a third height position measured by the height meter at an arrangement position of a third alignment mark that is not on a straight line extending in the predetermined direction.

8. The dicing device according to claim 7, wherein
the controller is configured or programmed to, when the difference between the first height position and the second height position is outside an allowable range, perform a control to enable positional adjustment of the wafer in the horizontal direction based on the third alignment mark imaged by the imager with the imaging focus adjusted based on a specified height plane, and the first alignment mark or the second alignment mark imaged by the imager with the imaging focus adjusted based on the specified height plane.

9. The dicing device according to claim 7, wherein
the controller is configured or programmed to control the height meter to measure the third height position without imaging the third alignment mark at the arrangement position of the third alignment mark using the imager when the difference between the first height position and the second height position is within an allowable range.

10. The dicing device according to claim 7, further comprising:
a laser lifting mechanism configured to move the laser irradiator in the upward-downward direction to adjust a laser focus of the laser beam; wherein
the controller is configured or programmed to perform a control to emit, to the wafer, the laser beam with the laser focus adjusted while simultaneously adjusting, using the laser lifting mechanism, a height position of the laser irradiator based on the height plane of the wafer specified based on height positions of three points on the wafer measured by the height meter.

11. The dicing device according to claim 1, wherein
the imager includes an infrared camera.

12. The dicing device according to claim 4, wherein
the imager includes a first camera and a second camera;
the first camera has a wider angle of view than the second camera; and
the second camera has a higher resolution than the first camera.

13. A semiconductor chip manufacturing method comprising:
imaging, by an imager, a plurality of alignment marks of a plurality of semiconductor chips on a wafer;
measuring, by a height meter, a height position of a surface of the wafer; and
emitting a laser beam to the wafer from a laser irradiator operable to emit the laser beam in order to dice the wafer into the plurality of semiconductor chips.

14. A semiconductor chip manufactured by a dicing device, the dicing device comprising:
a table configured to move a wafer including a plurality of semiconductor chips in at least one of a first direction in a horizontal direction or a second direction in the horizontal direction perpendicular to the first direction and rotate the wafer, while holding the wafer;
a laser irradiator configured to emit a laser beam to the wafer moved or rotated while being held by the table in order to dice the wafer into the plurality of semiconductor chips;
an imager configured to image a plurality of alignment marks of the plurality of semiconductor chips on the wafer; and
a height meter configured to measure a height position of a surface of the wafer.
